(19) United States
(12) Patent Application Publication
(10) Pub. No.: US 2026/0013098 A1
(43) Pub. Date: Jan. 8, 2026

(54) METHOD OF MANUFACTURING SEMICONDUCTOR MEMORY DEVICE

(71) Applicant: Samsung Electronics Co., Ltd., Suwon-si (KR)

(72) Inventors: Taekyun KIM, Suwon-si (KR); Jae Won SHIM, Seoul (KR); Min Jong LEE, Seoul (KR)

(73) Assignees: Samsung Electronics Co., Ltd., Suwon-si (KR); KOREA UNIVERSITY RESEARCH AND BUSINESS FOUNDATION, Seoul (KR)

(21) Appl. No.: 19/037,592

(22) Filed: Jan. 27, 2025

(30) Foreign Application Priority Data
Jul. 4, 2024 (KR) 10-2024-0088513

(51) Int. Cl. H10B 12/00

(52) U.S. Cl. CPC H10B 12/0335; H10B 12/315

(57) ABSTRACT

Provided is a method of manufacturing a semiconductor memory device, the method including preparing a substrate with a plurality of active regions defined by a device isolation film, forming, on the substrate, a plurality of lower electrodes electrically connected to the plurality of active regions, forming an electrode work function control layer, the electrode work function control layer including an organic material and conformally covering the plurality of lower electrodes, forming a capacitor dielectric layer on the plurality of lower electrodes covered by the electrode work function control layer, and forming an upper electrode on the capacitor dielectric layer, wherein the plurality of lower electrodes, the electrode work function control layer, the capacitor dielectric layer, and the upper electrode form a plurality of capacitor structures.

### CROSS-REFERENCE TO RELATED APPLICATION

This application is based on and claims priority under 35 U.S.C. § 119 to Korean Patent Application No. 10-2024-0088513, filed on Jul. 4, 2024, in the Korean Intellectual Property Office, the disclosure of which is incorporated by reference herein in its entirety.

### BACKGROUND

Some example embodiments of the inventive concepts relate to a method of manufacturing a semiconductor memory device, and more particularly, to a method of manufacturing a semiconductor memory device having a capacitor structure.

In accordance with the rapid development of the electronics industry and user demands, electronic devices are becoming increasingly smaller and lighter. Accordingly, higher integration is desired for semiconductor memory devices used in electronic devices and therefore design rules for the configurations of semiconductor memory devices are changing. Accordingly, it may be difficult to maintain reliability of semiconductor memory devices having a capacitor structure.

### SUMMARY

Some example embodiments of the inventive concepts provide a semiconductor memory device having a capacitor structure for improving reliability.

According to some example embodiments of the inventive concepts, there is provided a method of manufacturing a semiconductor memory device, the method including preparing a substrate with a plurality of active regions defined by a device isolation film, forming, on the substrate, a plurality of lower electrodes electrically connected to the plurality of active regions, forming an electrode work function control layer, the electrode work function control layer including an organic material and conformally covering the plurality of lower electrodes, forming a capacitor dielectric layer on the plurality of lower electrodes covered by the electrode work function control layer, and forming an upper electrode on the capacitor dielectric layer, wherein the plurality of lower electrodes, the electrode work function control layer, the capacitor dielectric layer, and the upper electrode form a plurality of capacitor structures.

According to some example embodiments of the inventive concepts, there is provided a method of manufacturing a semiconductor memory device, the method including preparing a substrate with a plurality of active regions defined by a device isolation film, forming a plurality of word lines extending across the plurality of active regions in a first horizontal direction, forming a plurality of bit lines positioned in the plurality of active regions and extending in a second horizontal direction, the second horizontal direction being perpendicular to the first horizontal direction, forming a plurality of buried contacts filling a lower portion of a space between the plurality of bit lines and are connected to the plurality of active regions, forming a plurality of landing pads filling an upper portion of the space between the plurality of bit lines and extend to the plurality of bit lines, forming a plurality of lower electrodes connected to the plurality of landing pads, forming an electrode work function control layer covering the plurality of lower electrodes as a monomolecular film, forming a capacitor dielectric layer on the plurality of lower electrodes covered by the electrode work function control layer, and forming an upper electrode on the capacitor dielectric layer. The plurality of lower electrodes, the electrode work function control layer, the capacitor dielectric layer, and the upper electrode form a plurality of capacitor structures.

According to some example embodiments of the inventive concepts, there is provided a method of manufacturing a semiconductor memory device, the method including preparing a substrate with a plurality of active regions defined by a device isolation film, forming a plurality of word lines extending across the plurality of active regions in a first horizontal direction, forming, on the plurality of word lines, a plurality of bit lines extending in a second horizontal direction perpendicular to the first horizontal direction, forming a plurality of direct contact conductive patterns connecting the plurality of bit lines to the plurality of active regions, forming a plurality of buried contacts filling a lower portion of a space between the plurality of bit lines, and the plurality of buried contacts being connected to the plurality of active regions, forming a landing pad material layer covering the plurality of bit lines, removing a portion of the landing pad material layer to form a recess portion, thereby forming the plurality of landing pads to be spaced apart from each other with the recess portion positioned therebetween, and the plurality of landing pads connecting to the plurality of buried contacts, forming a filling insulating layer filling the recess portion, and forming a plurality of capacitor structures connected to the plurality of landing pads. The forming of the plurality of capacitor structures comprises forming a plurality of lower electrodes connected to the plurality of landing pads on the filling insulating layer and on the plurality of landing pads, forming an electrode work function control layer comprising a self-assembled monolayer of an organic material, the self-assembled monolayer being formed by chemical adsorption on surfaces of the plurality of lower electrodes, forming a capacitor dielectric layer on the plurality of lower electrodes covered by the electrode work function control layer, and forming an upper electrode on the capacitor dielectric layer.

### BRIEF DESCRIPTION OF THE DRAWINGS

Some example embodiments described below will be more clearly understood from the following detailed description taken in conjunction with the accompanying drawings in which:

FIG. 1 is a block diagram of a semiconductor memory device, according to some example embodiments;

FIG. 2 is a schematic plan layout illustrating main components of a semiconductor memory device, according to some example embodiments;

FIGS. 3A to 13D are cross-sectional views illustrating a method of manufacturing a semiconductor memory device, according to some example embodiments, and FIGS. 14A to 14E are cross-sectional views of a semiconductor memory device, according to some example embodiments;

FIGS. 15A to 15E are cross-sectional views of a semiconductor memory device, according to some example embodiments;

FIGS. 16A to 16C and FIGS. 17A to 17C are diagrams illustrating example materials forming an electrode work function control layer according to a method of manufacturing a semiconductor memory device, according to some example embodiments;

FIG. 18 is a graph showing a work function change value for each example material forming an electrode work function control layer, according to some example embodiments;

FIGS. 19A and 19B are diagrams illustrating example materials forming an electrode work function control layer according to a method of manufacturing a semiconductor memory device, according to some example embodiments;

FIG. 20 is a graph showing a work function change value for each example material forming an electrode work function control layer, according to some example embodiments;

FIGS. 21A to 21E are diagrams which compare example materials forming an electrode work function control layer for surface roughness and surface energy, according to some example embodiments;

FIGS. 22A to 22C are diagrams showing electrical characteristics of a capacitor structure for each example material forming an electrode work function control layer, according to some example embodiments;

FIG. 23 is a layout diagram of a semiconductor memory device according to some example embodiments and FIG. 24 is a cross-sectional view taken along line X1-X1′ and line Y1-Y1′ in FIG. 23; and

FIG. 25 is a layout diagram of a semiconductor memory device according to some example embodiments and FIG. 26 is a perspective view of a semiconductor memory device.

### DETAILED DESCRIPTION OF THE EMBODIMENTS

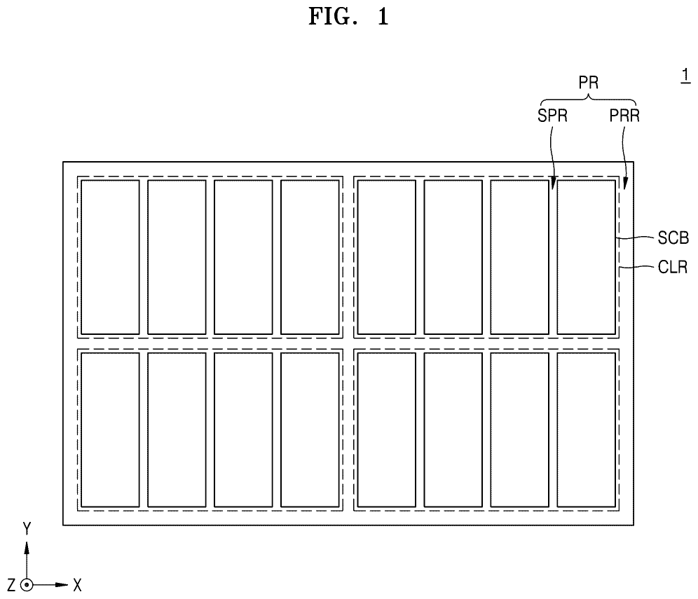

FIG. 1 is a block diagram of a semiconductor memory device, according to some example embodiments.

Referring to FIG. 1, a semiconductor memory device 1 may include a cell region CLR in which memory cells are arranged, and a main peripheral region PRR surrounding the cell region CLR.

According to some example embodiments, the cell region CLR may include sub-peripheral regions SPR which divide cell blocks SCB. A plurality of memory cells may be positioned in the cell blocks SCB.

Logic cells for in/out of electrical signals to the memory cells may be positioned in the main peripheral region PRR and the sub-peripheral region SPR. In some example embodiments, the main peripheral region PRR may be referred to as a peripheral circuit region and the sub-peripheral region SPR may be referred to as a core circuit region. A peripheral region PR may include the main peripheral region PRR and the sub-peripheral region SPR. That is, the peripheral region PR may include a core and peripheral circuit region including the peripheral circuit region and the core circuit region. In some example embodiments, at least a portion of the sub-peripheral region SPR may be provided only as a space for dividing the cell blocks SCB.

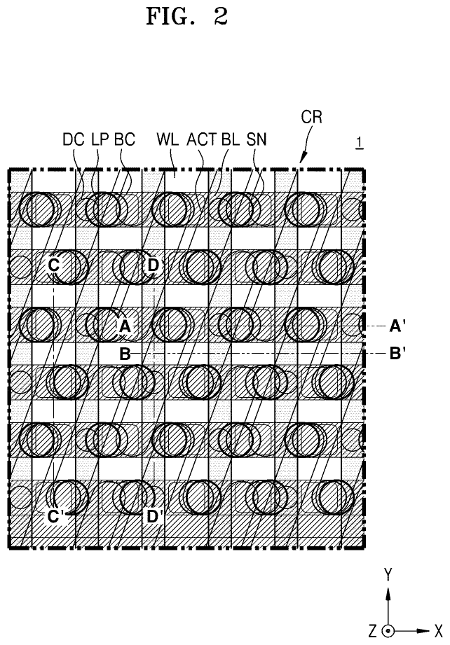

FIG. 2 is a schematic plan layout illustrating main components of a semiconductor memory device, according to some example embodiments.

Referring to FIG. 2, a semiconductor memory device 1 may include a memory cell region CR. The semiconductor memory device 1 may include a plurality of active regions ACT in the memory cell region CR. The memory cell region CR may include the cell block SCB, in which the plurality of memory cells are arranged, shown in FIG. 1. The plurality of active regions ACT arranged in the memory cell region CR may have a long axis in a diagonal direction with respect to a first horizontal direction (X direction) and a second horizontal direction (Y direction). In some example embodiments, the plurality of active regions ACT may be arranged in a row in the diagonal direction with respect to the first horizontal direction (X direction) and the second horizontal direction (Y direction) and may be arranged in a row in the second horizontal direction (Y direction).

A plurality of word lines WL may extend in parallel in the first horizontal direction (X direction) across the plurality of active regions ACT in the memory cell region CR. In some example embodiments, on one active region ACT, a pair of word lines WL may extend in parallel in the first horizontal direction (X direction). Above the plurality of word lines WL, a plurality of bit lines BL may extend in parallel in the second horizontal direction (Y direction) that intersects the first horizontal direction (X direction). In some example embodiments, one bit line BL may extend in the second horizontal direction (Y direction) on one active region ACT. The plurality of bit lines BL may be respectively connected to the plurality of active regions ACT through a plurality of direct contacts DC. The plurality of direct contacts DC may be positioned at the intersections of the plurality of bit lines BL and the plurality of active regions ACT.

In some example embodiments, a plurality of buried contacts BC may be formed between two adjacent bit lines BL among the plurality of bit lines BL. In some example embodiments, the plurality of buried contacts BC may be arranged in a row in each of the first horizontal direction (X direction) and the second horizontal direction (Y direction). In some example embodiments, a pair of buried contacts BC may be connected to one active region ACT. For example, one buried contact BC may be connected to each end of one active region ACT.

A plurality of landing pads LP may be respectively formed on the plurality of buried contacts BC. The plurality of landing pads LP may at least partially overlap with the plurality of buried contacts BC. In some example embodiments, each of the plurality of landing pads LP may extend to the top of one of two adjacent bit lines BL.

A plurality of storage nodes SN may be respectively formed on the plurality of landing pads LP. The plurality of storage nodes SN may be formed on the top of the plurality of bit lines BL. The plurality of storage nodes SN may include lower electrodes of a plurality of capacitors, respectively. The storage node SN may be connected to the active region ACT through the landing pad LP and the buried contact BC.

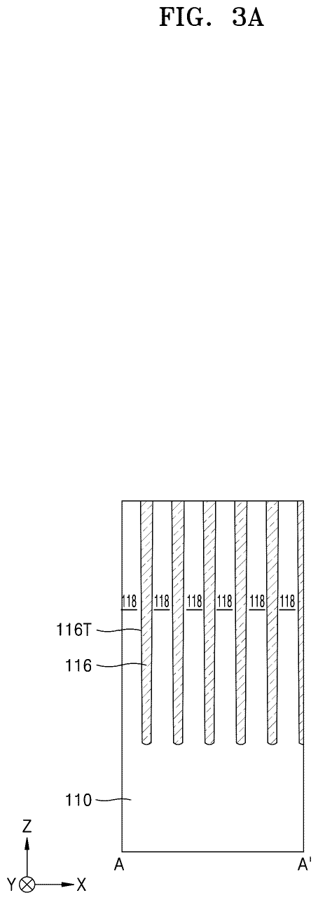

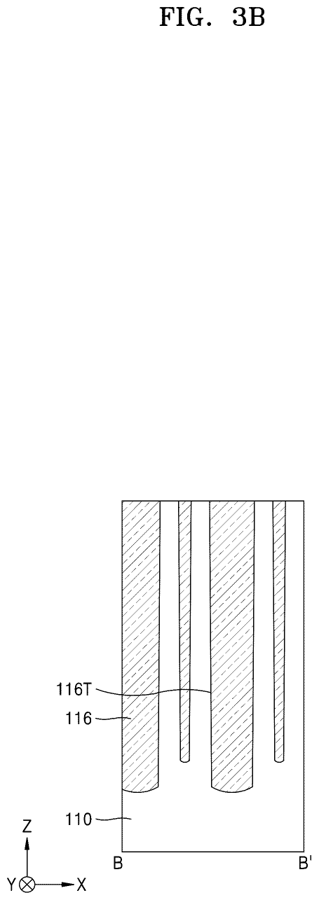

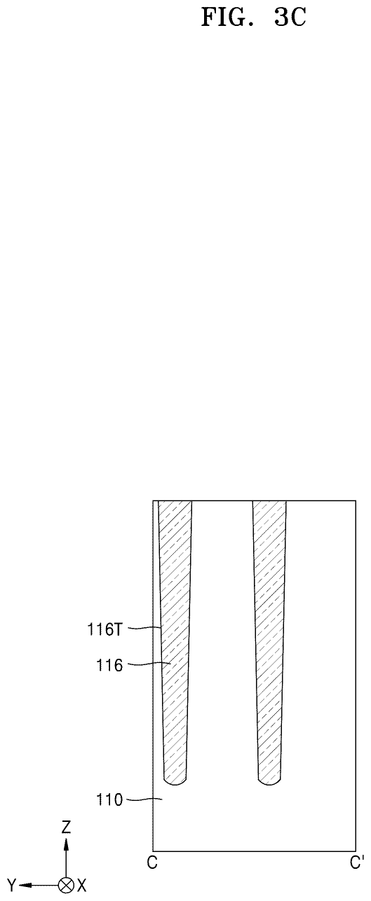

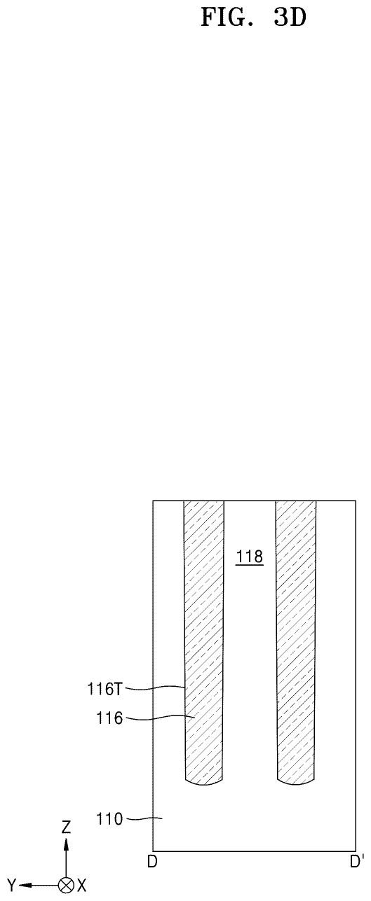

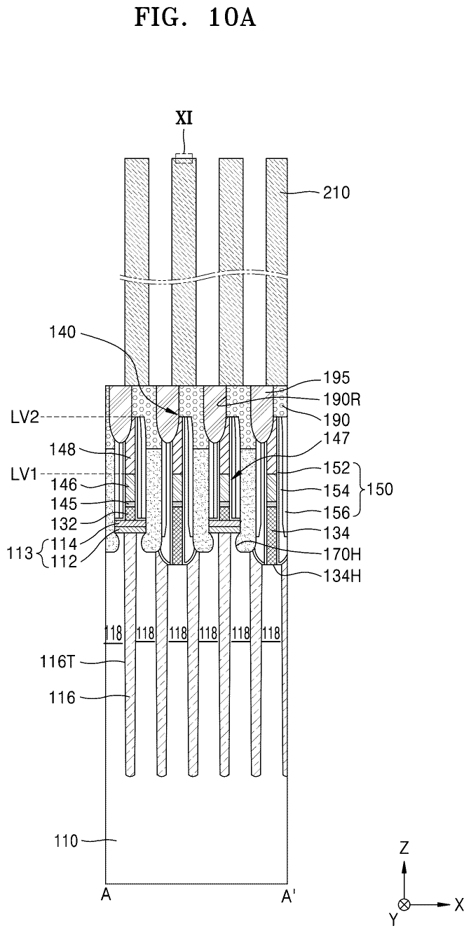

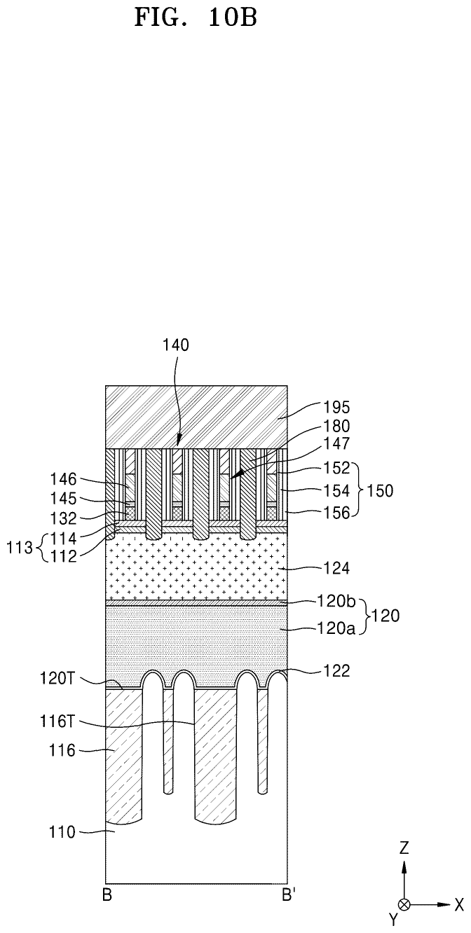

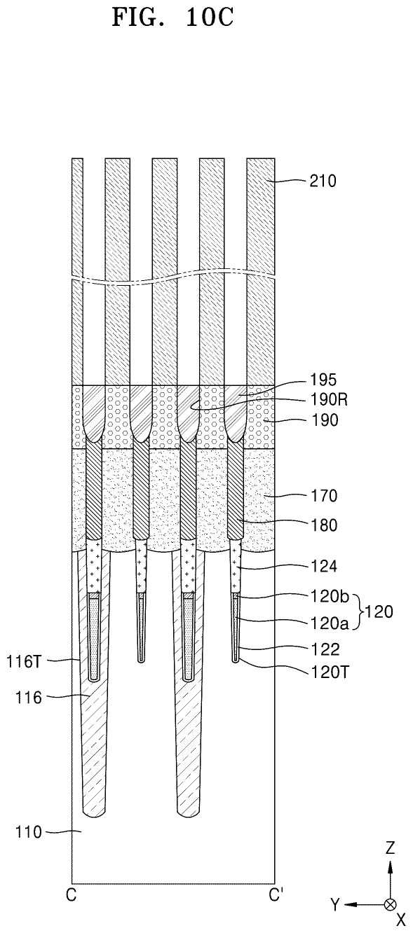

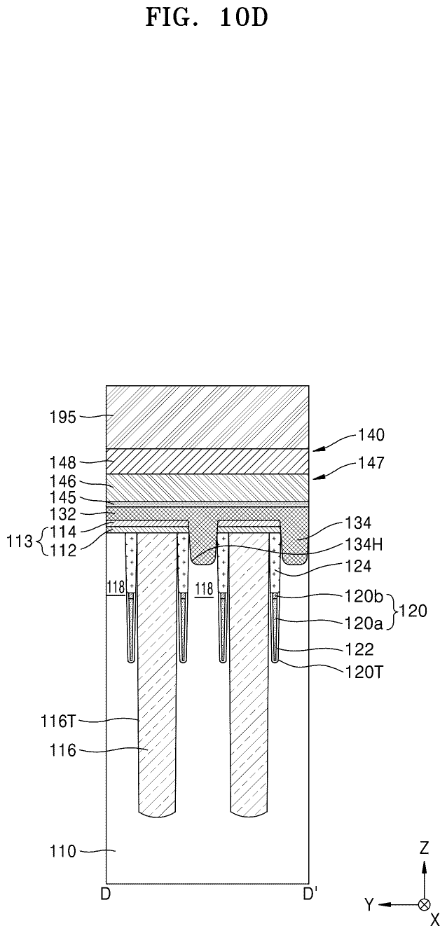

FIGS. 3A to 13D are cross-sectional views illustrating a method of manufacturing a semiconductor memory device, according to some example embodiments, and FIGS. 14A to 14E are cross-sectional views of a semiconductor memory device, according to some example embodiments. Specifically, FIGS. 3A, 4A, 5A, 6A, 7A, 8A, 9A, 10A, 12A, 13A, and 14A are cross-sectional views taken along line A-A′ in FIG. 2; FIGS. 3B, 4B, 5B, 6B, 7B, 8B, 9B, 10B, 12B, 13B, and 14B are cross-sectional views taken along line B-B′ in FIG. 2; FIGS. 3C, 4C, 5C, 6C, 7C, 8C, 9C, 10C, 12C, 13C, and 14C are cross-sectional views taken along line C-C′ in FIG. 2; FIGS. 3D, 4D, 5D, 6D, 7D, 8D, 9D, 10D, 12D, 13D and 14D are cross-sectional views taken along line D-D′ in FIG. 2; FIGS. 11A and 11B are enlarged cross-sectional views of portion XI in FIG. 10A; and FIG. 14E is an enlarged cross-sectional view of portion XIVE in FIG. 14A.

Referring to FIGS. 3A to 3D, a device isolation trench 116T may be formed in a substrate 110 and a device isolation film 116 may be formed to fill the device isolation trench 116T. In some example embodiments, the device isolation trench 116T and a plurality of active regions 118 defined by the device isolation trench 116T may be formed through an EUV lithography process.

The substrate 110 may include, for example, silicon (Si), crystalline Si, polycrystalline Si, or amorphous Si. In other embodiments, the substrate 110 may include a semiconductor element, such as germanium (Ge), or at least one compound semiconductor selected from among silicon germanium (SiGe), silicon carbide (SiC), gallium arsenide (GaAs), indium arsenide (InAs), and indium phosphide (InP). In some example embodiments, the substrate 110 may have a silicon on insulator (SOI) structure. For example, the substrate 110 may include a buried oxide (BOX) layer. However, example embodiments are not limited thereto. The substrate 110 may include a conductive region, for example, a well doped with impurities or a structure doped with impurities. The device isolation film 116, for example, may include a material including at least one of silicon oxide (SiO), silicon nitride (SiN), and silicon oxynitride (SiON). However, example embodiments are not limited thereto. The device isolation film 116 may include a single layer including one type of an insulating film, a double layer including two types of insulating films, or a multilayer including a combination of at least three types of insulating films. For example, the device isolation film 116 may include a double layer or a multilayer including an oxide film and a nitride film. However, according to the inventive concepts, the configuration of the device isolation film 116 is not limited to the above.

The plurality of active regions 118 may be defined by the device isolation film 116 on the substrate 110 in the memory cell region CR. Like the active region ACT illustrated in FIG. 2, the active region 118 may have a short axis and a long axis in a plan view and may have a relatively long island shape extending in the long axis direction. The plurality of active regions 118 may be arranged in a row in the diagonal direction with respect to the first horizontal direction (X direction) and the second horizontal direction (Y direction) and may be arranged in a row in the second horizontal direction (Y direction).

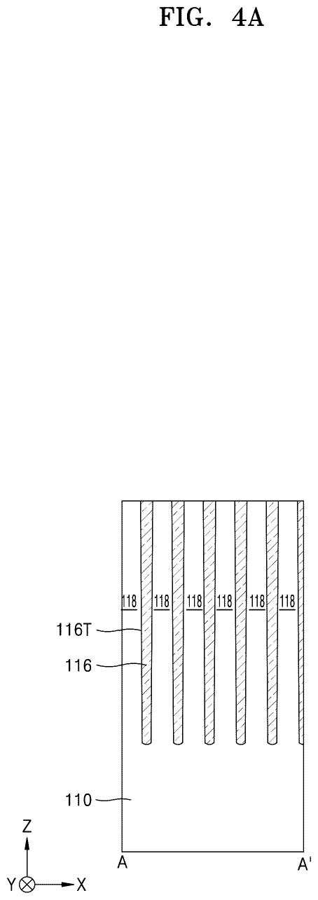

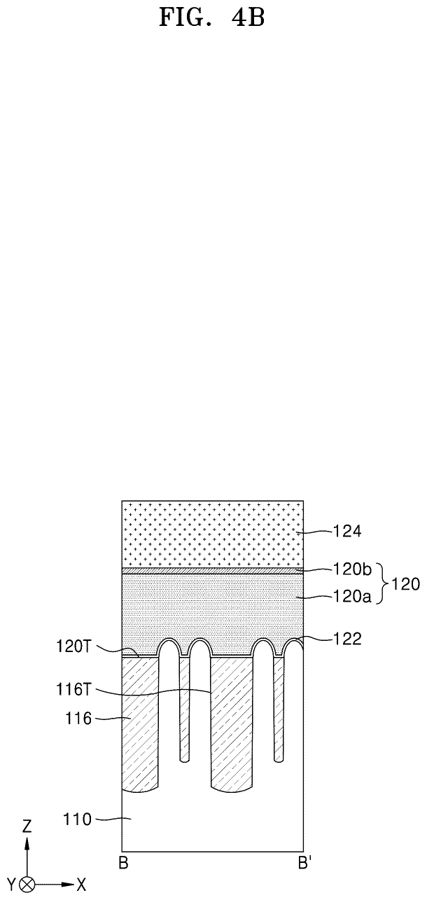

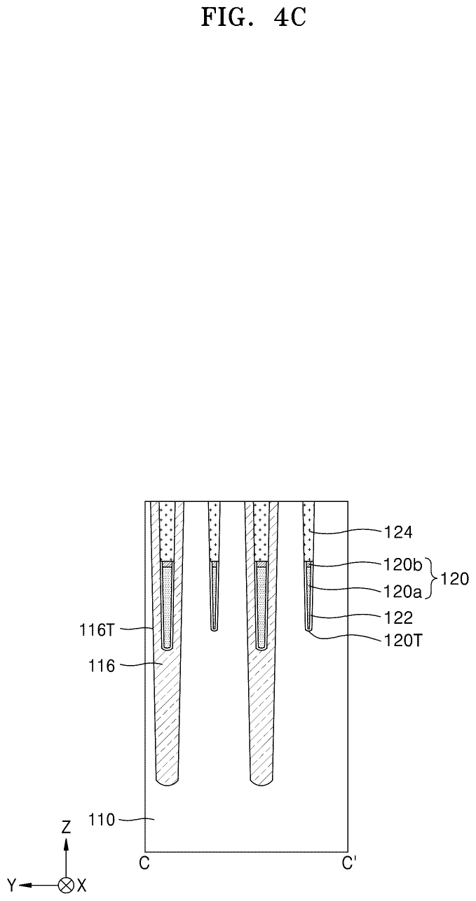

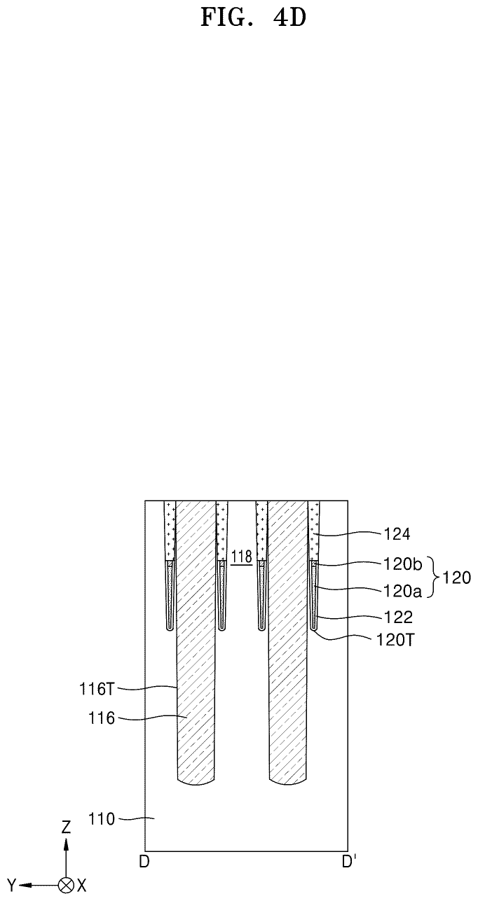

Referring to FIGS. 4A to 4D together, a portion of the active region 118 and a portion of the device isolation film 116 may be removed to form a plurality of word line trenches 120T in the substrate 110. The plurality of word line trenches 120T may each have a line shape as the plurality of word line trenches 120T extend in parallel in the first horizontal direction (X direction) and are arranged at about equal intervals in the second horizontal direction (Y direction) while crossing the active regions 118. In some example embodiments, a step may be formed on the bottom surface of each of the plurality of word line trenches 120T.

Inside the plurality of word line trenches 120T, a plurality of gate dielectric films 122, a plurality of word lines 120, and a plurality of buried insulating films 124 may be sequentially formed. The plurality of word lines 120 may constitute the plurality of word lines WL illustrated in FIG. 2. The plurality of word lines 120 may each have a line shape as the plurality of word lines 120 extend in parallel in the first horizontal direction (X direction) and are arranged at about equal intervals in the second horizontal direction (Y direction) while crossing the active regions 118. A top surface of each of the plurality of word lines 120 may be at a lower level than a top surface of the substrate 110. The bottom portion of the plurality of word lines 120 may have a concavo-convex shape, and a saddle fin transistor (FinFET) may be formed in the plurality of active regions 118.

Each of the plurality of word lines 120 may have a structure in which a lower word line layer 120a and an upper word line layer 120b are stacked. For example, the lower word line layer 120a may include a metal material, a conductive metal nitride, or a combination thereof. In some example embodiments, the lower word line layer 120a may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. However, example embodiments are not limited thereto. For example, the upper word line layer 120b may include doped polysilicon. However, example embodiments are not limited thereto. In some example embodiments, the lower word line layer 120a may include a core layer and a barrier layer between the core layer and the gate dielectric film 122.

In some example embodiments, before or after forming the plurality of word lines 120, impurity ions may be injected into the active region 118 on both sides of the word lines 120 on the substrate 110 to form a source region and a drain region within the plurality of active regions 118.

The gate dielectric film 122 may include at least one selected from SiO, SiN, SiON, oxide/nitride/oxide (ONO), and high-k dielectrics having a higher dielectric constant than SiO. For example, the gate dielectric film 122 may have a dielectric constant of about 10 to about 25.

The buried insulating film 124 may include at least one material selected from SiO, SiN, SiON, and a combination thereof. However, example embodiments are not limited thereto.

In some example embodiments, in the process of forming the plurality of gate dielectric films 122, the plurality of word lines 120, and the plurality of buried insulating films 124, an upper portion of the device isolation film 116 is removed so that the top surface of the substrate 110, the top surface of the device isolation film 116, and the top surfaces of the plurality of buried insulating films 124 may be at substantially the same level and may be coplanar or substantially coplanar.

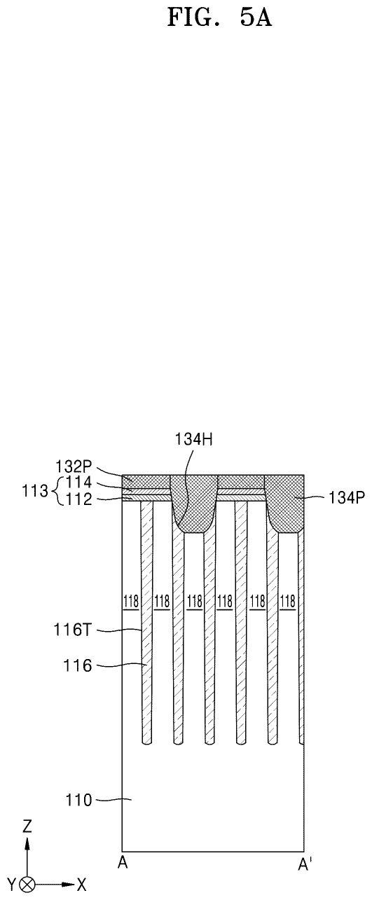

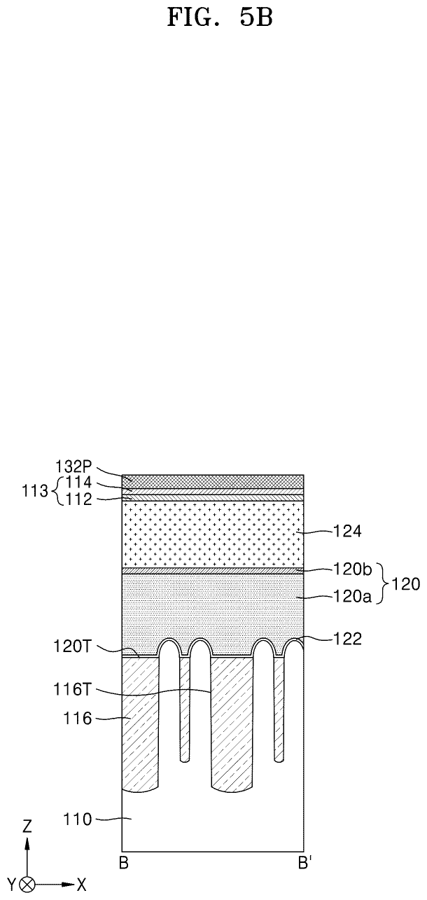

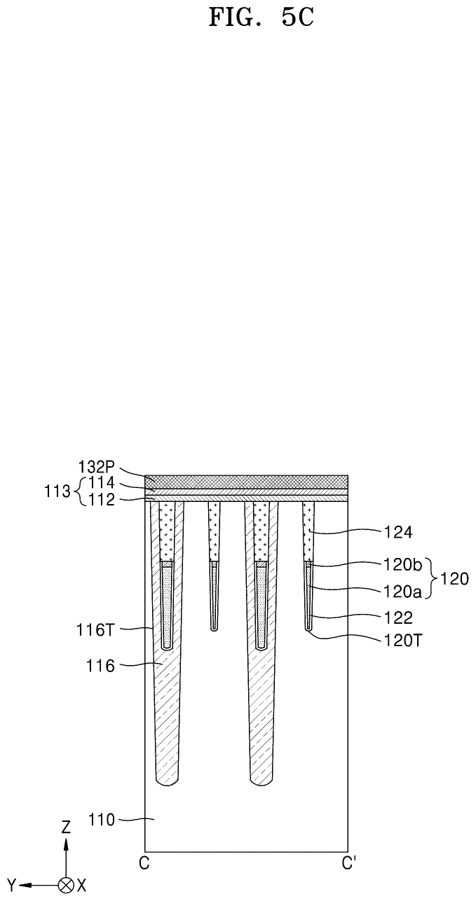

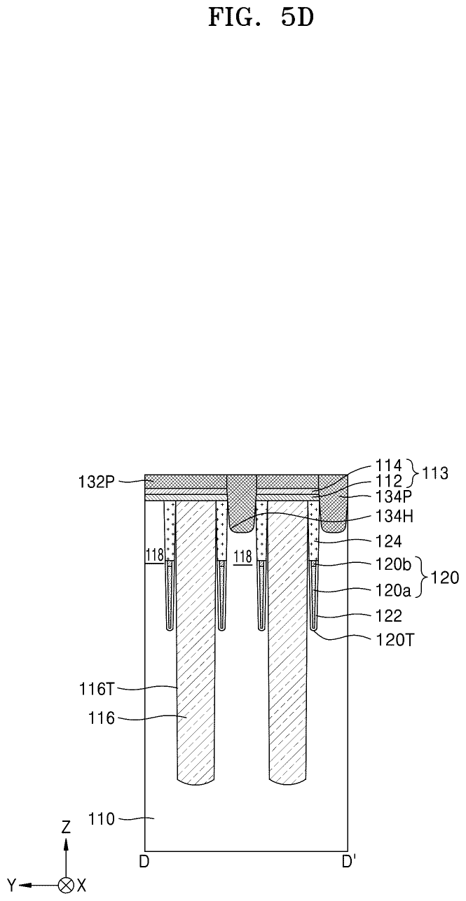

Referring to FIGS. 5A to 5D together, the device isolation film 116 forms an insulating structure 113 covering the plurality of active regions 118. For example, the insulating structure 113 may include a SiO film, a SiN film, a SiON film, a metallic dielectric film, or a combination thereof. However, example embodiments are not limited thereto. In some example embodiments, the insulating structure 113 may be formed by stacking a plurality of insulating films including a first insulating film pattern 122 and a second insulating film pattern 124. In some example embodiments, the first insulating film pattern 122 may include a SiO film and the second insulating film pattern 124 may include a SiON film. In other embodiments, the first insulating film pattern 122 may include a non-metallic dielectric film, and the second insulating film pattern 124 may include a metallic dielectric film. However, example embodiments are not limited thereto.

Thereafter, after forming a conductive semiconductor layer 132P on the insulating structure 113, a direct contact hole 134H which penetrates the conductive semiconductor layer 132P and the insulating structure 113 and exposes a source region within the active region 118 is formed and a direct contact conductive layer 134P, which fills the direct contact hole 134H, is formed. In some example embodiments, the direct contact hole 134H may extend into the active region 118, that is, the source region. The conductive semiconductor layer 132P, for example, may include doped polysilicon. In some example embodiments, the conductive semiconductor layer 132P and the direct contact conductive layer 134P may include the same type of material. For example, the direct contact conductive layer 134P may include doped polysilicon. In other embodiments, the conductive semiconductor layer 132P and the direct contact conductive layer 134P may include different types of materials. For example, the direct contact conductive layer 134P may include an epitaxial silicon layer, a metal, or a metal compound as a conductive material. However, example embodiments are not limited thereto. In some example embodiments, the direct contact conductive layer 134P may include a conductive material which includes a metal, such as Ti and W, or a compound of a metal, such as Ti and W, and a non-metal, such as Si, carbon (C), boron (B), and nitrogen (N). For example, the direct contact conductive layer 134P may include TiN, tungsten carbide (WC), or tungsten silicide (WSi). However, example embodiments are not limited thereto.

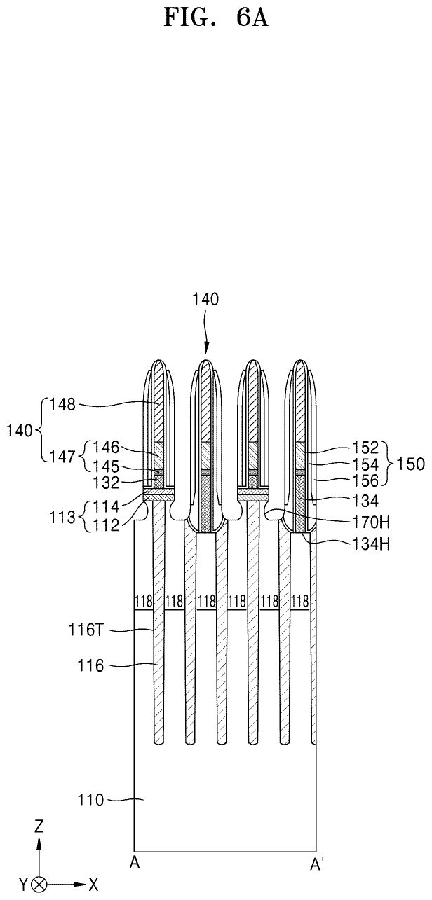

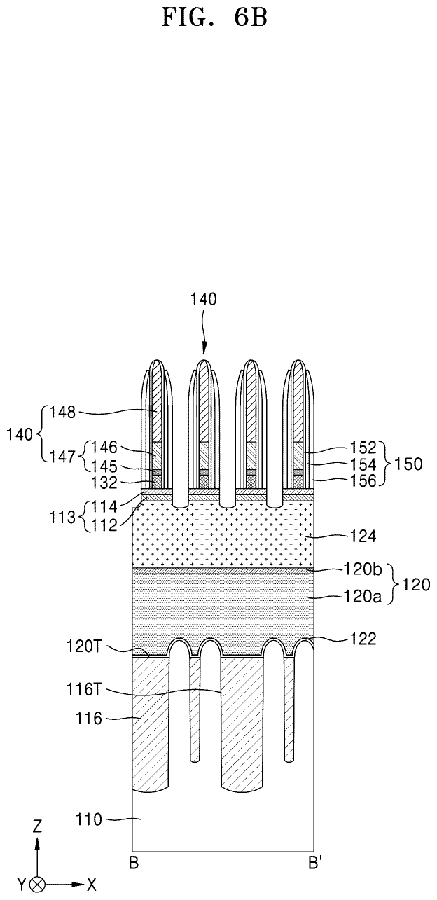

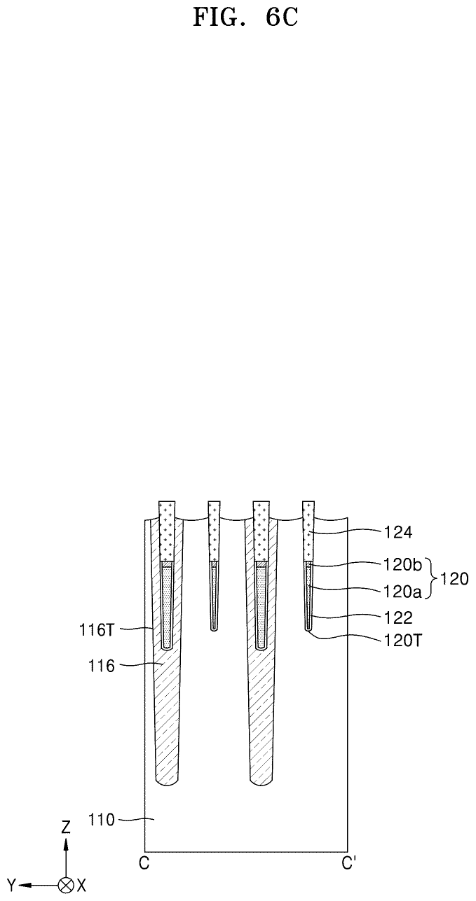

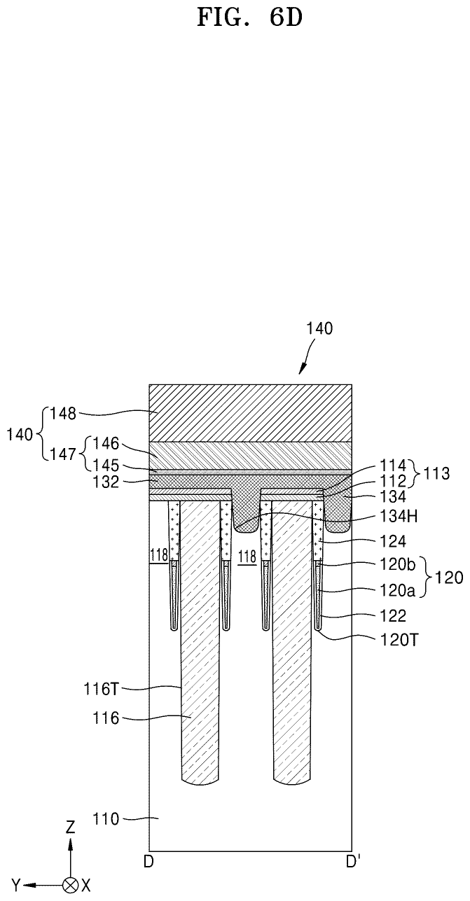

Referring to FIGS. 5A to 5D and FIGS. 6A to 6D together, a metallic conductive layer and an insulating capping layer for covering the conductive semiconductor layer 132P and the direct contact conductive layer 134P and forming the bit line structure 140 are sequentially formed. In some example embodiments, the metallic conductive layer may have a structure in which a first metallic conductive layer and a second metallic conductive layer are stacked. The first metallic conductive layer, the second metallic conductive layer, and the insulating capping layer are etched to form a plurality of bit lines 147 having a structure in which a first metallic conductive pattern 145 and a second metallic conductive pattern 146, which have a line shape, are stacked, and a plurality of insulating capping lines 148 covering the plurality of bit lines 147.

In some example embodiments, the first metallic conductive pattern 145 may include TIN or Ti—Si—N (TSN) and the second metallic conductive pattern 146 may include W, or W and WSiₓ. However, example embodiments are not limited thereto. In some example embodiments, the first metallic conductive pattern 145 may perform the function of a diffusion barrier. In some example embodiments, the plurality of insulating capping lines 148 may include a SiN film. However, example embodiments are not limited thereto.

One bit line 147 and one insulating capping line 148 covering one bit line 147 may form one bit line structure 140. The plurality of bit line structures 140, which each include the bit line 147 and the insulating capping line 148 covering the bit line 147, may extend in parallel in the second horizontal direction (Y direction) parallel to the main surface of the substrate 110. The plurality of bit lines 147 may respectively constitute the plurality of bit lines BL illustrated in FIG. 2. In some example embodiments, the bit line structure 140 may further include a conductive semiconductor pattern 132, which is a part of the conductive semiconductor layer 132P between the insulating structure 113 and the first metallic conductive pattern 145.

In the etching process to form the plurality of bit lines 147, a part of the conductive semiconductor layer 132P and a part of the direct contact conductive layer 134P, which do not vertically overlap with the bit line 147, may be removed through the etching process to form the plurality of conductive semiconductor patterns 132 and the plurality of direct contact patterns 134. The insulating structure 113 may function as an etch stop film in the etching process to form the plurality of bit lines 147, the plurality of conductive semiconductor patterns 132, and the plurality of direct contact patterns 134. The plurality of direct contact patterns 134 may respectively constitute the plurality of direct contacts DC illustrated in FIG. 2. The plurality of bit lines 147 may be electrically and respectively connected to the plurality of active regions 118 through the plurality of direct contact patterns 134. The conductive semiconductor pattern 132, for example, may include doped polysilicon. The direct contact pattern 134 may include doped polysilicon, a metal, or a metal compound as a conductive material. For example, the direct contact pattern 134 may include a conductive material which is a metal, such as Ti and W, or a compound of a metal, such as Ti and W, and a non-metal, such as Si, C, B, and N. However, example embodiments are not limited thereto. In some example embodiments, the direct contact patterns 134 may include TiN, WC, or WSi. However, example embodiments are not limited thereto.

Both sidewalls of each of the plurality of bit line structures 140 may be covered with an insulating spacer structure 150. A plurality of insulating spacer structures 150 may each include a first insulating structure 152, a second insulating structure 154, and a third insulating structure 156. The second insulating structure 154 may include a material having a lower dielectric constant than the first insulating structure 152 and the third insulating structure 156. In some example embodiments, the first insulating structure 152 and the third insulating structure 156 may include a nitride film and the second insulating structure 154 may include an oxide film. In some example embodiments, the first insulating structure 152 and the third insulating structure 156 may include a nitride film and the second insulating structure 154 may include a material having an etch selectivity with respect to the first insulating structure 152 and the third insulating structure 156. For example, when the first insulating structure 152 and the third insulating structure 156 include a nitride film, the second insulating structure 154 includes an oxide film but may be removed in a subsequent process to become an air spacer.

Each of a plurality of buried contact holes 170H may be formed between the plurality of bit lines 147. The plurality of buried contact holes 170H may have an internal space limited by the active region 118 and the insulating spacer structure 150 covering the sidewalls of each of the two neighboring bit lines 147 among the plurality of bit lines 147.

The plurality of buried contact holes 170H may be formed by removing portions of the insulating structure 113 and the active region 118 using the plurality of insulating capping lines 148 and the insulating spacer structure 150 covering the sidewalls of each of the plurality of bit line structures 140 as an etching mask. In some example embodiments, after performing an anisotropic etching process to remove portions of the insulating structure 113 and the active region 118 using the plurality of insulating capping lines 148 and the insulating spacer structure 150 covering sidewalls of each of the plurality of bit line structures 140 as an etching mask, an isotropic etching process may be performed to further remove other portions of the active region 118 to expand the space limited by the active region 118, thereby forming the plurality of buried contact holes 170H.

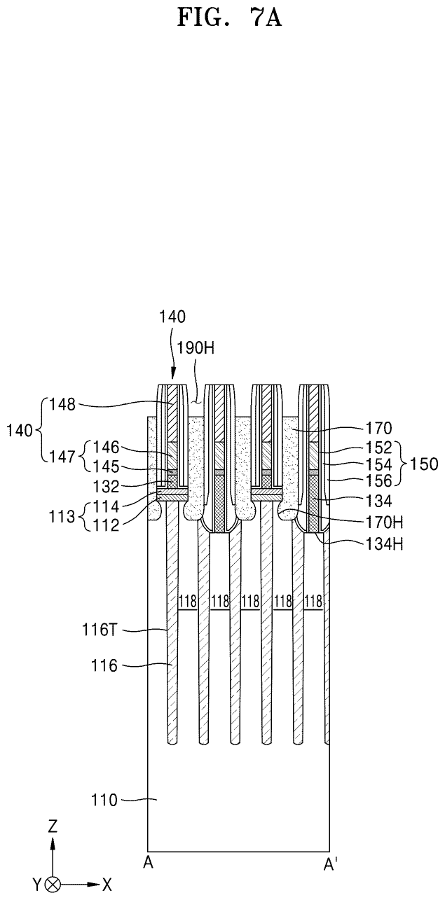

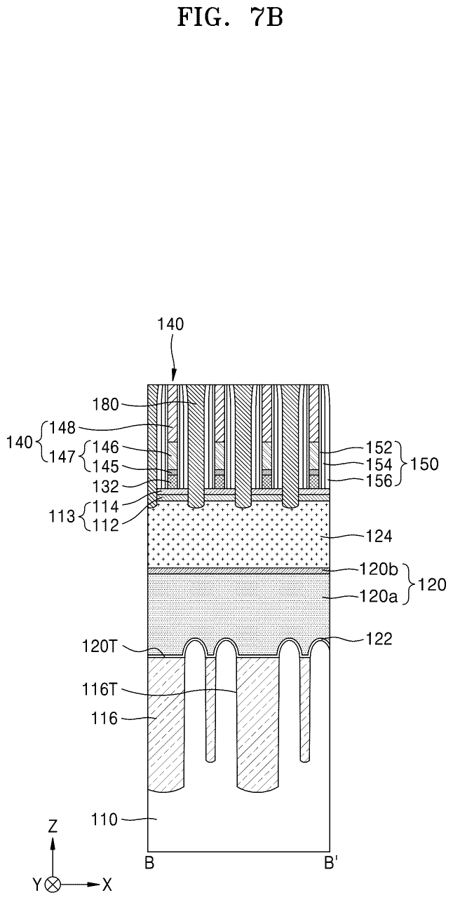

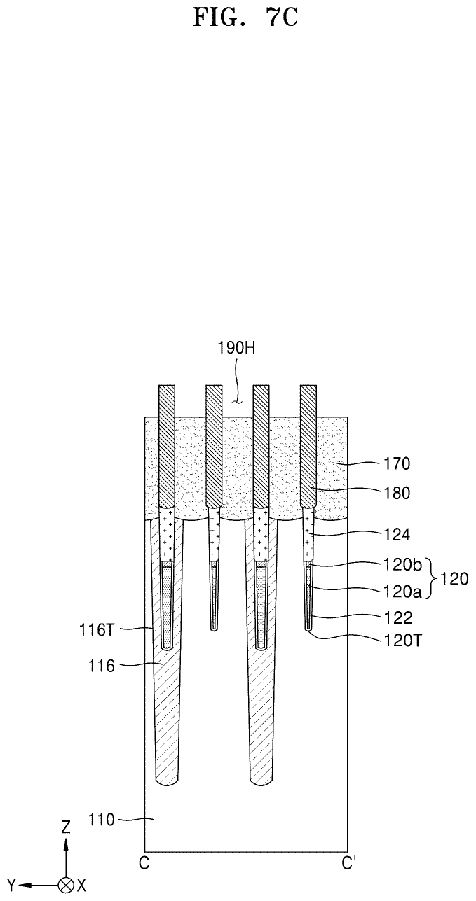

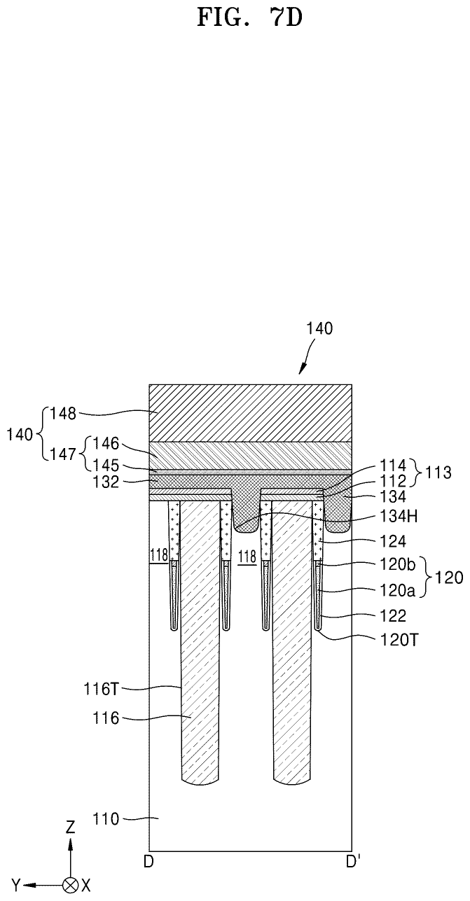

Referring to FIGS. 7A to 7D together, a plurality of buried contacts 170 and a plurality of insulating fences 180 are formed in the space between the plurality of insulating spacer structures 150 covering both sidewalls of each of the plurality of bit line structures 140. The plurality of buried contacts 170 and the plurality of insulating fences 180 may be arranged alternately between a pair of insulating spacer structures 15 facing each other among the plurality of insulating spacer structures 150 covering both sidewalls of each of the plurality of bit line structures 140, i.e., in the second horizontal direction (Y direction). For example, the plurality of buried contacts 170 may include polysilicon. For example, the plurality of insulating fences 180 may include a nitride film.

In some example embodiments, the plurality of buried contacts 170 may be arranged in a row in each of the first horizontal direction (X direction) and the second horizontal direction (Y direction). Each of the plurality of buried contacts 170 may extend from the active region 118 in a vertical direction (Z direction) perpendicular to the substrate 110. The plurality of buried contacts 170 may constitute the plurality of buried contacts BC illustrated in FIG. 2.

The plurality of buried contacts 170 may be positioned in a space limited by the plurality of insulating fences 180 and the plurality of insulating spacer structures 150 that cover both sidewalls of the plurality of bit line structures 140. The plurality of buried contacts 170 may fill a lower portion of the space between the plurality of insulating spacer structures 150 covering both sidewalls of each of the plurality of bit line structures 140.

The level of the top surfaces of the plurality of buried contacts 170 may be less than the level of the top surfaces of the plurality of insulating capping lines 148. The top surfaces of the plurality of insulating fences 180 and the top surfaces of the plurality of insulating capping lines 148 may be at the same level with respect to the vertical direction (Z direction).

A plurality of landing pad holes 190H may be limited by the plurality of insulating spacer structures 150 and the plurality of insulating fences 180. The plurality of buried contacts 170 may be exposed at the bottom surfaces of the plurality of landing pad holes 190H.

In the process of forming the plurality of buried contacts 170 and/or the plurality of insulating fences 180, upper portions of the insulating capping line 148 included in the bit line structure 140 and the insulating spacer structure 150 may be removed, thereby lowering the level of the top surface of the bit line structure 140.

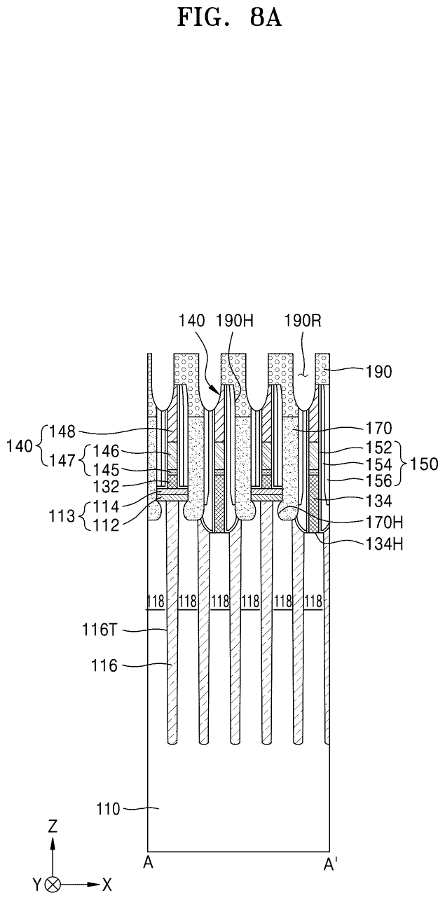

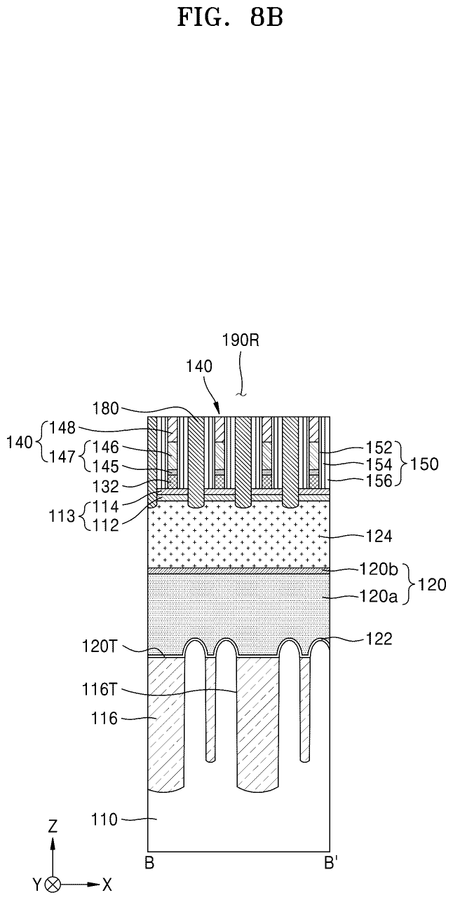

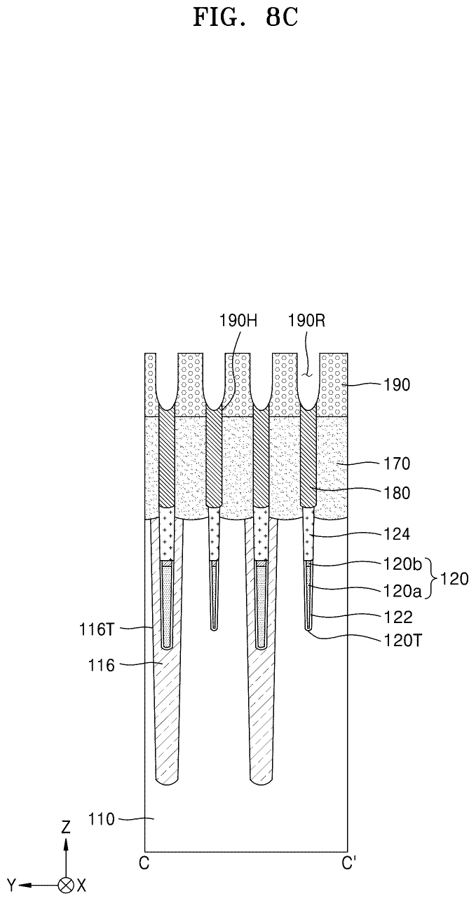

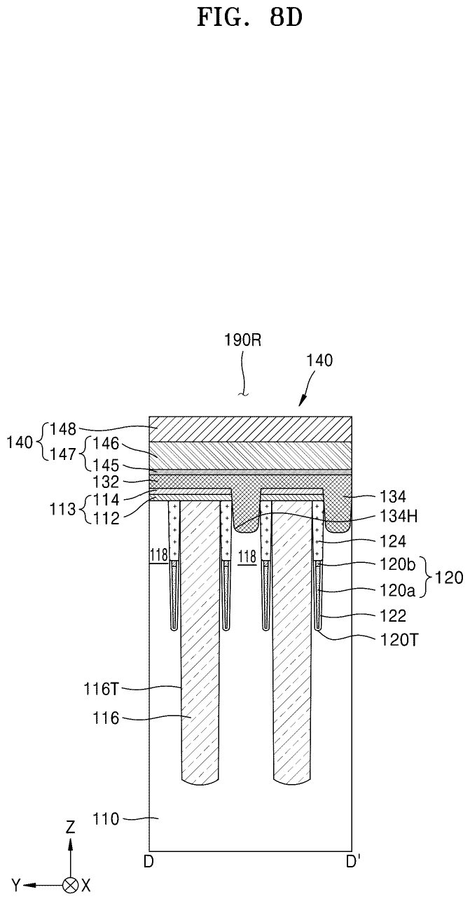

Referring to FIGS. 8A to 8D together, a landing pad material layer is formed to fill the plurality of landing pad holes 190H and cover the plurality of bit line structures 140. In some example embodiments, the landing pad material layer may include a conductive barrier film and a conductive pad material layer on the conductive barrier film. For example, the conductive barrier film may include a metal, a conductive metal nitride, or a combination thereof. In some example embodiments, the conductive barrier film may have a Ti/TiN stacked structure. However, example embodiments are not limited thereto. In some example embodiments, the conductive pad material layer may include W. However, example embodiments are not limited thereto.

In some example embodiments, a metal silicide film may be formed on the plurality of buried contacts 170 before forming the landing pad material layer. The metal silicide film may be positioned between the plurality of buried contacts 170 and the landing pad material layer. The metal silicide film may include cobalt silicide (CoSiₓ), nickel silicide (NiSiₓ), or manganese silicide (MnSiₓ), but is not limited thereto. However, example embodiments are not limited thereto.

Thereafter, by removing portions of the landing pad material layer, a plurality of landing pads 190, which fill at least a portion of the plurality of landing pad holes 190H, extend to the plurality of bit line structures 140, and are divided into a plurality of pieces by a recess portion 190R, are formed.

The plurality of landing pads 190 may be spaced apart from each other with the recess portion 190R in between. The plurality of landing pads 190 may be positioned on the plurality of buried contacts 170 and may extend to the plurality of bit line structures 140. In some example embodiments, the plurality of landing pads 190 may extend to the plurality of bit lines 147. As the plurality of landing pads 190 are positioned on the plurality of buried contacts 170, the plurality of landing pads 190 and the plurality of buried contacts 170 corresponding thereto may be electrically connected to each other. The buried contact 170 and the landing pad 190 that correspond to each other may be referred to together as a contact plug. The plurality of landing pads 190 may be connected to the active regions 118 through the plurality of buried contacts 170. The plurality of landing pads 190 may respectively constitute the plurality of landing pads LP illustrated in FIG. 2.

The buried contact 170 may be positioned between two adjacent bit line structures 140, and the landing pad 190 may extend to one bit line structure 140 from among two adjacent bit line structures 140 with the buried contact 170 in between.

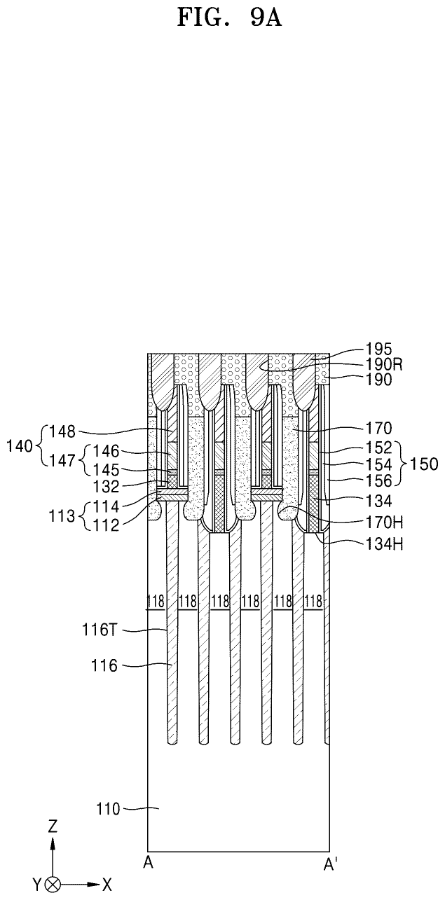

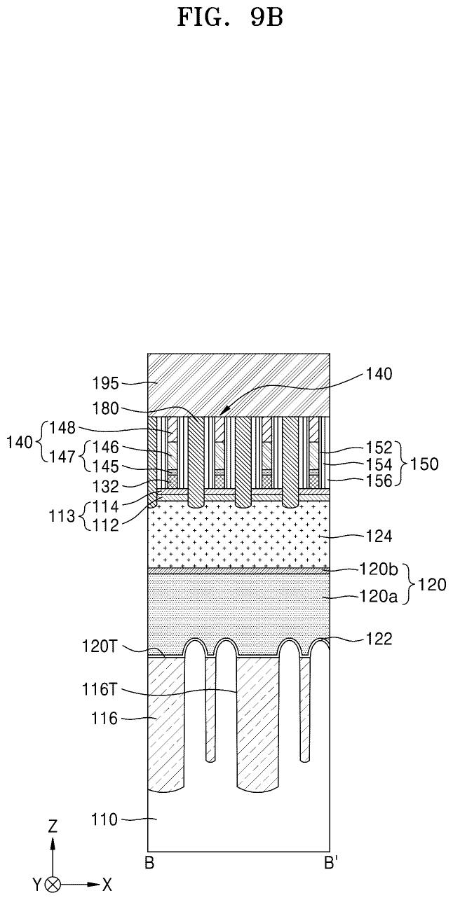

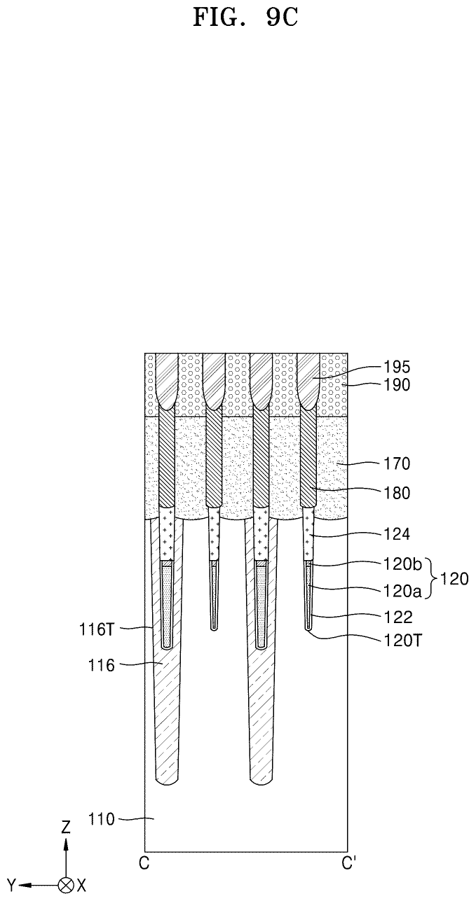

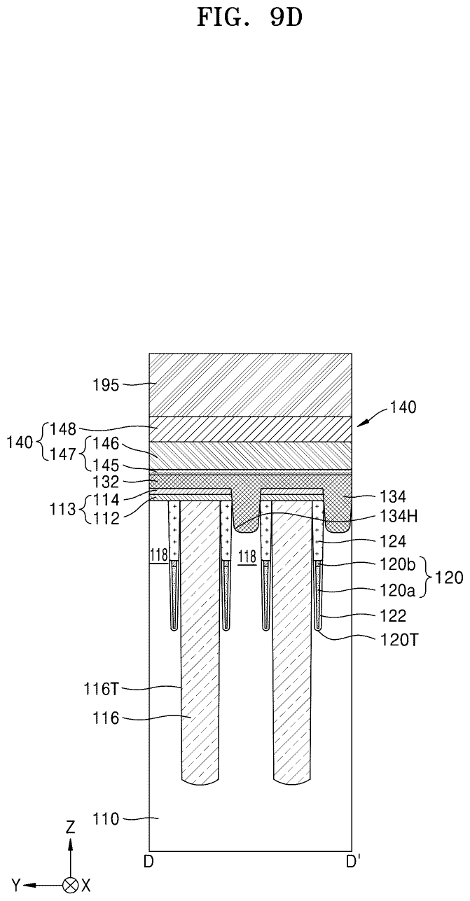

Referring to FIGS. 9A to 9D together, a filling insulating layer 195 may be formed to fill the recess portion 190R. In some example embodiments, the filling insulating layer 195 may include an interlayer insulating layer and an etch stop film. For example, the interlayer insulating layer may include an oxide and the etch stop film may include a nitride. The top surface of the filling insulating layer 195 and the top surface of the landing pad 190 are shown to be at the same level in FIGS. 9A and 9C but the inventive concepts are not limited thereto.

Referring to FIGS. 10A to 10D together, a plurality of lower electrodes 210 are formed on the plurality of landing pads 190. The plurality of lower electrodes 210 may be electrically connected to the plurality of landing pads 190, respectively. The plurality of lower electrodes 210 may respectively constitute the plurality of storage nodes SN illustrated in FIG. 2.

The plurality of lower electrodes 210 may each have a column shape, that is, a pillar shape, filled inside to have a circular horizontal cross-section but are not limited thereto. In some example embodiments, the plurality of lower electrodes 210 may each have a cylindrical shape with a closed lower portion. In some example embodiments, the plurality of lower electrodes 210 may be arranged in a honeycomb shape to be arranged in a zigzag pattern with respect to the first horizontal direction (X direction) or the second horizontal direction (Y direction). In other embodiments, the plurality of lower electrodes 210 may be arranged in a matrix form to be arranged in a row in each of the first horizontal direction (X direction) and the second horizontal direction (Y direction). For example, the plurality of lower electrodes 210 may include a metal, such as Si, W, or copper (Cu) doped with impurities, or a conductive metal compound, such as TiN. However, example embodiments are not limited thereto. In some example embodiments, the plurality of lower electrodes 210 may include TiN. However, example embodiments are not limited thereto. In some example embodiments, at least one support pattern contacting the sidewalls of the plurality of lower electrodes 210 may be further formed. For example, the plurality of the support patterns may be further formed in contact with the sidewalls of the plurality of lower electrodes 210 and at different vertical levels.

Referring to FIG. 11A, a preliminary work function control material 215P is supplied to the lower electrode 210. The preliminary work function control material 215P may be supplied to the lower electrodes 210 in gas or liquid state. The preliminary work function control material 215P may include an organic material capable of forming a self-assembled monolayer (SAM). In some example embodiments, the preliminary work function control material 215P may include phosphonic acid. For example, the preliminary work function control material 215P may include a carbazole-based material with phosphonic acid as a fixed group. In some example embodiments, the preliminary work function control material 215P may include 2PACz ([2-(9H-carbazol-9-yl)ethyl]phosphonic acid), Br-2PACz ([2-(3,6-Dibromo-9H-carbazol-9-yl)ethyl]phosphonic acid), or MeO-2PACZ ([2-(3,6-Dimethoxy-9H-carbazol-9-yl)ethyl]phosphonic acid). In some example embodiments, the preliminary work function control material 215P may include FBPA (2,3,4,5,6-Pentafluorobenzylphosphonic acid), TIPs (6,13-Bis(triisopropylsilylethynyl)pentacene), 4-FTP (4-fluorothiophenol), or MEH-PPV (Poly [2-methoxy-5-(2-ethylhexyloxy)-1,4-phenylenevinylene]), Aba (4-Aminobenzoic acid).

Referring to FIGS. 11A and 11B together, the molecules that make up the preliminary work function control material 215P are arranged on the surface of the lower electrode 210 by chemical adsorption to form an electrode work function control layer 215, which includes the SAM. The electrode work function control layer 215 may include a monomolecular film including an organic material. In some example embodiments, the electrode work function control layer 215 may include phosphonic acid. For example, the electrode work function control layer 215 may include a carbazole-based material with phosphonic acid as a fixed group. In some example embodiments, the electrode work function control layer 215 may include 2PACz-based material, such as 2PACz ([2-(9H-carbazol-9-yl)ethyl]phosphonic acid), Br-2PACz ([2-(3,6-Dibromo-9H-carbazol-9-yl)ethyl]phosphonic acid), or MeO-2PACz ([2-(3,6-Dimethoxy-9H-carbazol-9-yl)ethyl]phosphonic acid). In some example embodiments, the electrode work function control layer 215 may include FBPA (2,3,4,5,6-Pentafluorobenzylphosphonic acid), TIPS (6,13-Bis(triisopropylsilylethynyl) pentacene), 4-FTP (4-fluorothiophenol), or MEH-PPV (Poly [2-methoxy-5-(2-ethylhexyloxy)-1,4-phenylenevinylene]), Aba (4-Aminobenzoic acid).

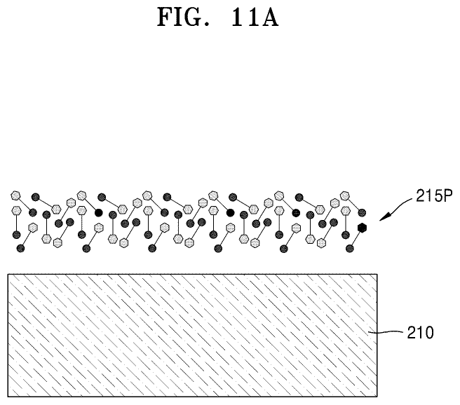

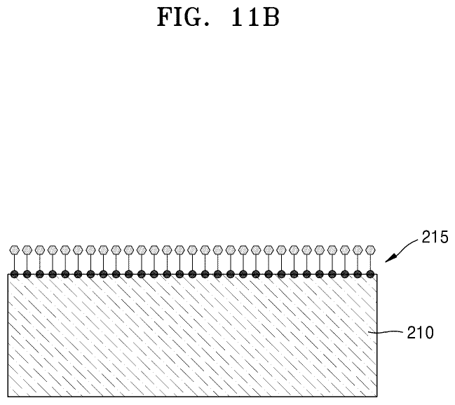

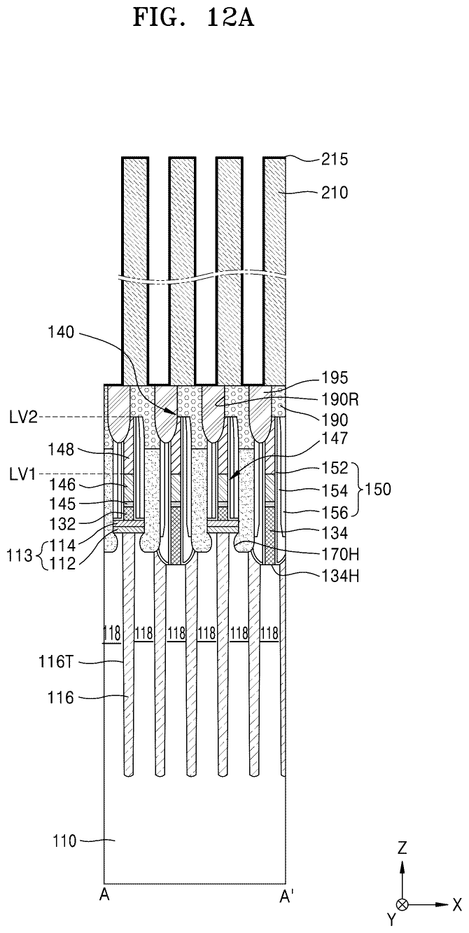

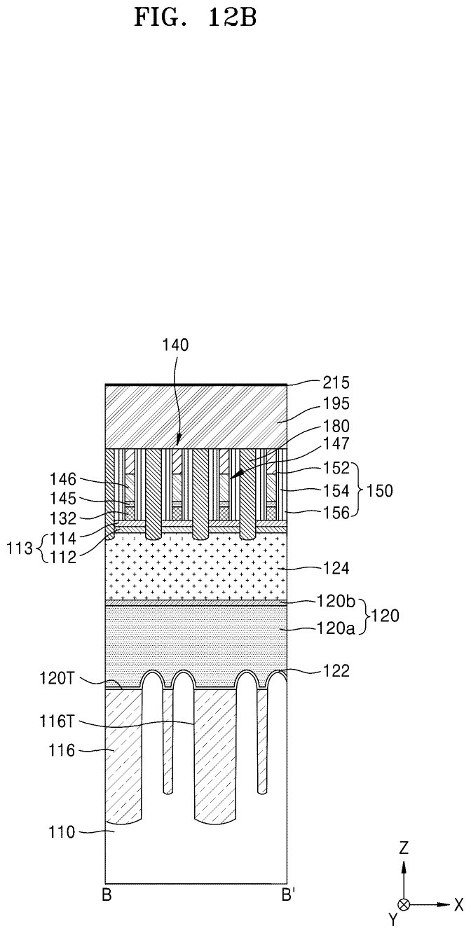

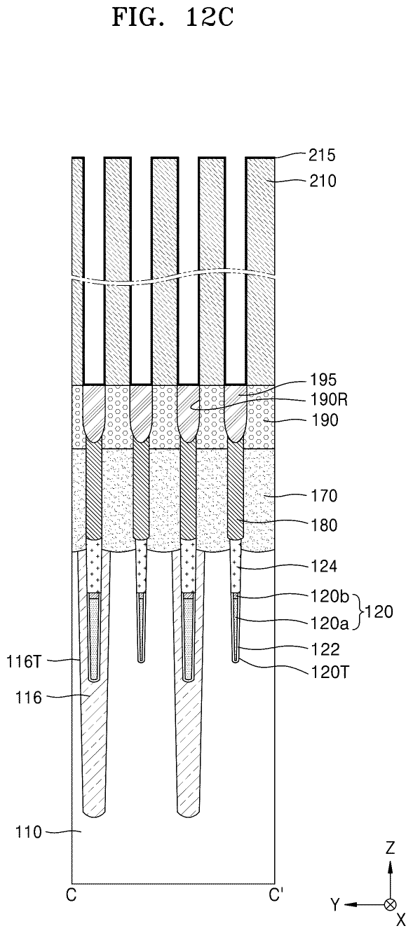

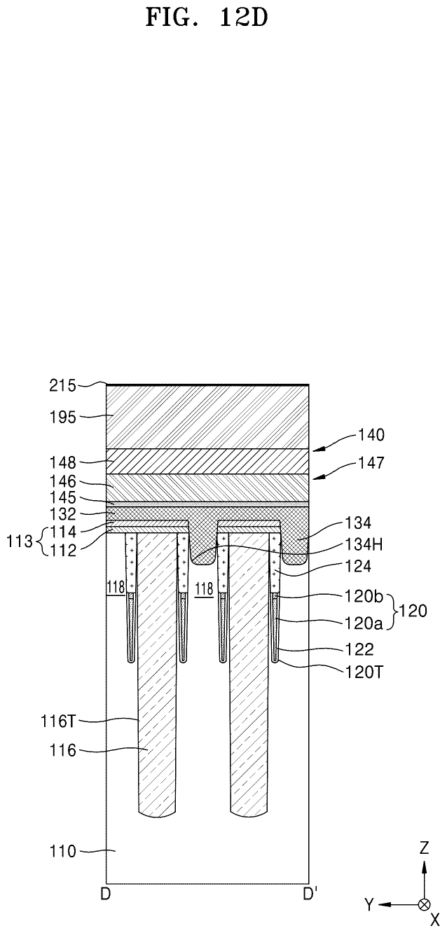

Referring to FIG. 11B and FIGS. 12A to 12D together, the electrode work function control layer 215 may be formed as a monomolecular film that conformally covers the exposed surfaces of each of the plurality of lower electrodes 210, that is, the top surface and sidewalls of each of the plurality of lower electrodes 210. In some example embodiments, the electrode work function control layer 215 may further cover a portion of the top surface of each of the plurality of landing pads 190 and a portion of the top surface of the filling insulating layer 195, which are not covered by the plurality of lower electrodes 210. For example, the electrode work function control layer 215 may be formed as a monomolecular film covering the exposed surfaces of each of the plurality of lower electrodes 210, the plurality of landing pads 190, and the filling insulating layer 195. The electrode work function control layer 215 covering the surfaces of the lower electrode 210 may control the work function of the lower electrode 210. For example, the lower electrode 210 and the electrode work function control layer 215 covering the lower electrode 210 may increase or decrease the work function, compared to the lower electrode 210.

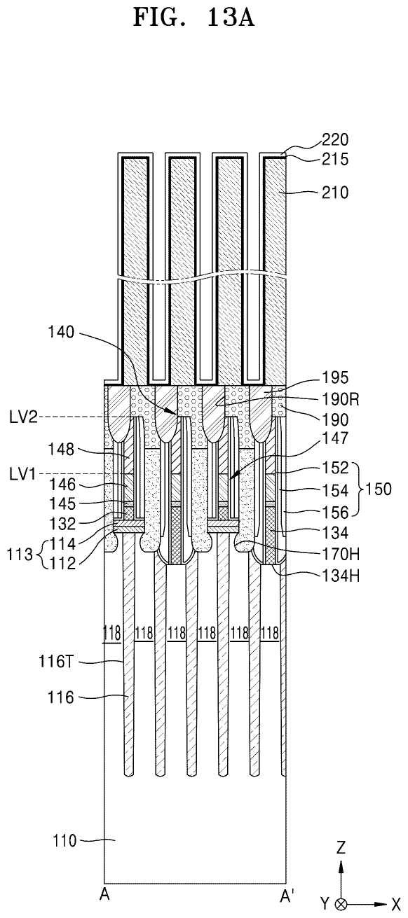

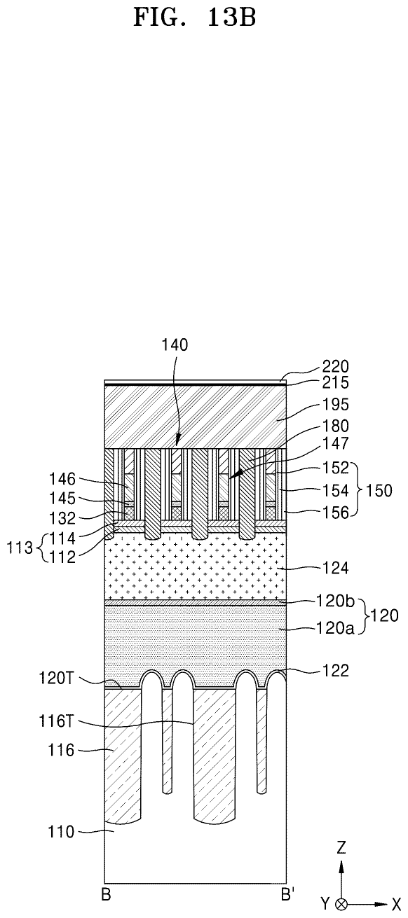

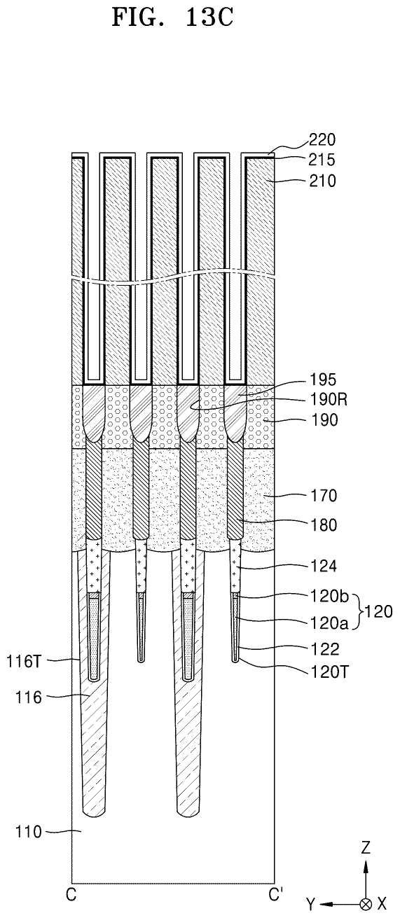

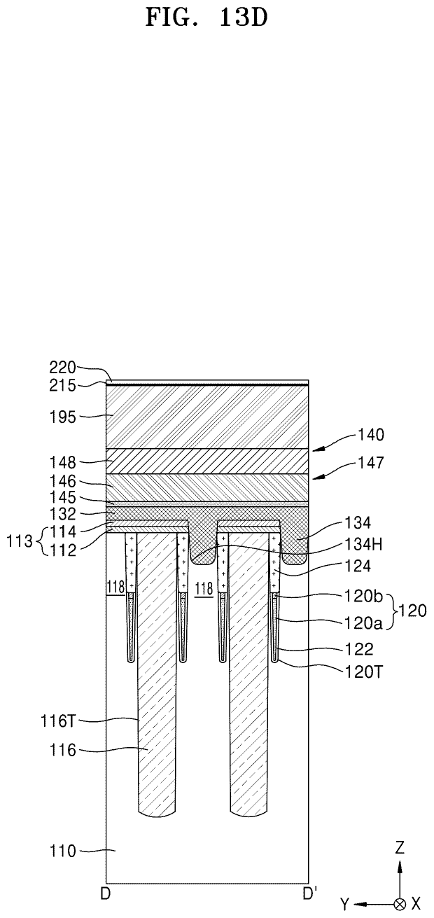

Referring to FIGS. 13A to 13D together, a capacitor dielectric layer 220 is formed on the electrode work function control layer 215 covering the plurality of lower electrodes 210. The capacitor dielectric layer 220 may conformally cover the surfaces of the electrode work function control layer 215 covering the plurality of lower electrodes 210. In some example embodiments, the capacitor dielectric layer 220 may be formed integrally to cover the plurality of lower electrodes 210 within a certain area, for example, one memory cell region (CR in FIG. 2). The capacitor dielectric layer 220 may include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, or a combination thereof. However, example embodiments are not limited thereto.

Referring to FIGS. 14A to 14E together, an upper electrode 230 is formed on the capacitor dielectric layer 220. The plurality of lower electrodes 210, the electrode work function control layer 215, the capacitor dielectric layer 220, and the upper electrode 230 may form a plurality of capacitor structures 200. In some example embodiments, the upper electrode 230 may be integrally formed to cover the plurality of lower electrodes 210 within a certain area, for example, one memory cell region (CR in FIG. 2).

The upper electrode 230 may include, for example, a semiconductor material, such as doped polysilicon and doped polycrystalline SiGe, a metallic material, such as W, Ru, Pt, Ir, V, Mo, Ta, Nb, In, TiN, VN, MON, TaN, NbN, InN, RuO, PtO, IrO, TiO, VO, MoO, TaO, NbO, InO, SRO(SrRuO), BSRO((Ba,Sr)RuO), CRO(CaRuO), BaRuO, La(Sr,Co)O, or a combination thereof. However, example embodiments are not limited thereto. In some example embodiments, the upper electrode 230 may include a metal material, such as W or ruthenium (Ru). However, example embodiments are not limited thereto. In other embodiments, the upper electrode 230 may have a structure in which a semiconductor material and a metal-based material are stacked. For example, the upper electrode 230 may have a structure in which at least two layers are stacked, including a metal-based material and a semiconductor material covering the metal-based material, or may have a structure in which at least three layers are stacked, including a semiconductor material, a metallic material covering the semiconductor material, and a semiconductor material covering the metallic material.

Thereafter, a cover insulating layer 260 covering the upper electrode 230 is formed. In some example embodiments, the bottom surface of the cover insulating layer 260 may be in direct contact with the top surface of the upper electrode 230. The cover insulating layer 260, for example, may include SiO. For example, the cover insulating layer 260 may include an oxide film or an ultra-low K (ULK) film. The oxide film may be formed of at least one film selected from among a borophosphosilicate glass (BPSG) film, a phosphosilicate glass (PSG) film, a borosilicate glass (BSG) film, an un-doped silicate glass (USG) film, a tetra ethyl ortho silicate (TEOS) film, or a high density plasma (HDP) film. However, example embodiments are not limited thereto. The ULK film may include, for example, any one film selected from among a SiOC film and a SiCOH film having an ultra-low dielectric constant K of about 2.2 to about 2.4.

By removing a portion of the cover insulating layer 260, a wiring contact hole MCH is formed. The upper electrode 230 may be exposed at the bottom surface of the wiring contact hole MCH. The wiring contact hole MCH may extend through the cover insulating layer 260 to the upper electrode 230. In some example embodiments, the wiring contact hole MCH may extend into the upper electrode 230. For example, the wiring contact hole MCH may extend into the upper electrode 230 through the cover insulating layer 260 but may not extend to the capacitor dielectric layer 220. The vertical level of the bottom surface of the wiring contact hole MCH may be less than the vertical level of the top surface of the upper electrode 230 but greater than the vertical level of the top surface of the capacitor dielectric layer 220.

A wiring contact plug 310 that fills the wiring contact hole MCH may be formed. The wiring contact plug 310 may be in contact with the upper electrode 230 but may not be in contact with the capacitor dielectric layer 220. In some example embodiments, the wiring contact plug 310 may extend into the upper electrode 230. For example, the wiring contact plug 310 may extend into the upper electrode 230 through the cover insulating layer 260 but may not extend to the capacitor dielectric layer 220. The vertical level of the bottom surface of the wiring contact plug 310 may be less than the vertical level of the top surface of the upper electrode 230 but may be greater than the vertical level of the top surface of the capacitor dielectric layer 220. Each of the wiring contact hole MCH and the wiring contact plug 310 may extend from the bottom to the top in the vertical direction (Z direction) and may have a tapered shape with an increasing horizontal width.

The wiring contact plug 310 may include a wiring contact barrier layer 312 and a wiring contact filling layer 314. The wiring contact barrier layer 312 may conformally cover the inner surfaces of the wiring contact hole MCH, that is, the inner sidewalls and bottom surface thereof, and the wiring contact filling layer 314 may cover the wiring contact barrier layer 312 to fill the wiring contact hole MCH. For example, the wiring contact barrier layer 312 may include Ti, Ta, TiN, TaN, and the like. However, example embodiments are not limited thereto. For example, the wiring contact filling layer 314 may include a metal, such as W. However, example embodiments are not limited thereto.

On the cover insulating layer 260 in which the wiring contact plug 310 is formed, a wiring line 320 connected to the wiring contact plug 310 may be formed, thereby forming the semiconductor memory device 1. The plurality of wiring lines 320 may include a metal, such as aluminum (Al), Cu, and W. However, example embodiments are not limited thereto.

The semiconductor memory device 1 includes: a substrate 110 with a plurality of active regions 118; a plurality of gate dielectric films 122, a plurality of word lines 120, and the plurality of buried insulating films 124, which are sequentially formed inside the plurality of word line trenches 120T across the plurality of active regions 118 within the substrate 110; the insulating structure 113 covering the device isolation film 116, the plurality of active regions 118, and the plurality of buried insulating films 124; the plurality of bit line structures 140 on the insulating structure 113; the plurality of insulating spacer structures 150 covering both sidewalls of the plurality of bit line structures 140; the plurality of buried contacts 170 connected to the plurality of active regions 118 and filling a lower portion of the space defined by the plurality of insulating fences 180 and the plurality of insulating spacer structures 150 and the plurality of landing pads 190 filling an upper portion thereof and extending to an upper portion of the bit line structure 140; the plurality of capacitor structures 200 including the plurality of lower electrodes 210 connected to the plurality of landing pads 190, the electrode work function control layer 215, the capacitor dielectric layer 220, and the upper electrode 230; the wiring contact plug 310 connected to the upper electrode 230; and the wiring line 320 connected to the wiring contact plug 310.

The plurality of lower electrodes 210 may each have a first horizontal width W1. The plurality of lower electrodes 210 may be spaced apart from each other by a second horizontal width W2. The second horizontal width W2 may be the minimum separation width in the horizontal direction between adjacent lower electrodes 210 among the plurality of lower electrodes 210. In some example embodiments, the second horizontal width W2 may have a value greater than the first horizontal width W1. For example, the first horizontal width W1 may be about 10 nm to about 14 nm and the second horizontal width W2 greater than the first horizontal width W1 may be about 12 nm to about 16 nm.

In some example embodiments, the electrode work function control layer 215 may cover the exposed surfaces of each of the plurality of lower electrodes 210, the plurality of landing pads 190, and the filling insulating layer 195. The electrode work function control layer 215 may have a first thickness T1 that is uniform or substantially uniform and may cover the exposed surfaces of each of the plurality of lower electrodes 210, the plurality of landing pads 190, and the filling insulating layer 195. For example, the electrode work function control layer 215 may cover the top surface and sidewalls of each of the plurality of lower electrodes 210, and the portion of the top surface of each of the plurality of landing pads 190 and the portion of the top surface of the filling insulating layer 195, which are not covered by the plurality of lower electrodes 210. The electrode work function control layer 215 may include a monomolecular film. The capacitor dielectric layer 220 may cover the electrode work function control layer 215. The capacitor dielectric layer 220 may have a second thickness T2 that is uniform or substantially uniform and may cover the electrode work function control layer 215. The second thickness T2 may have a value greater than the first thickness T1. For example, the first thickness T1 may be about 10 Å to about 20 Å and the second thickness T2 may be about 30 Å to about 70 Å. In some example embodiments, the second thickness T2 may have a value that is at least 4 times greater than first thickness T1. For example, the first thickness T1 may be about 12 Å and the second thickness T2 may be about 50 Å. However, example embodiments are not limited thereto.

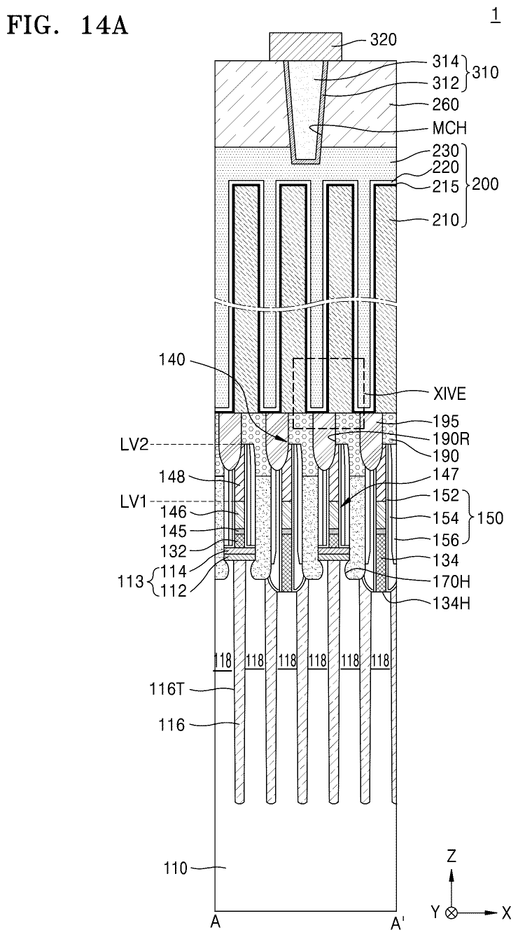

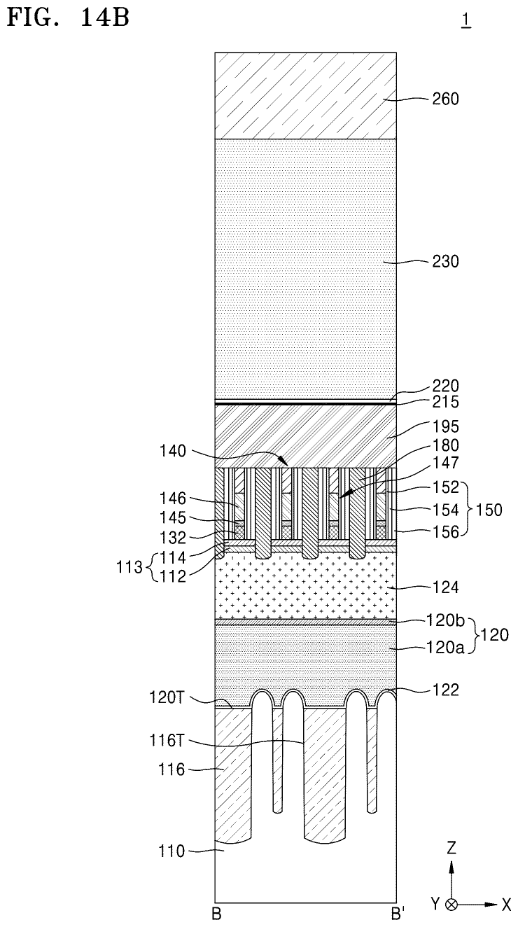

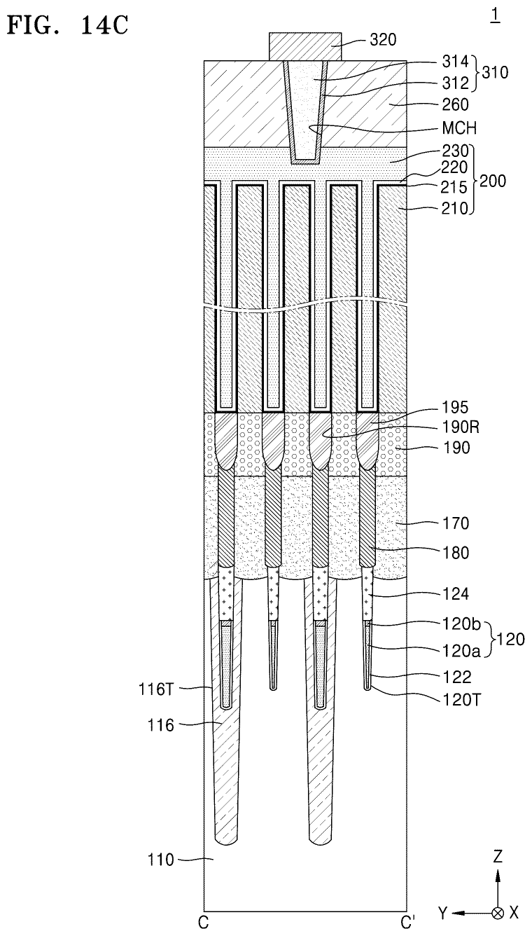

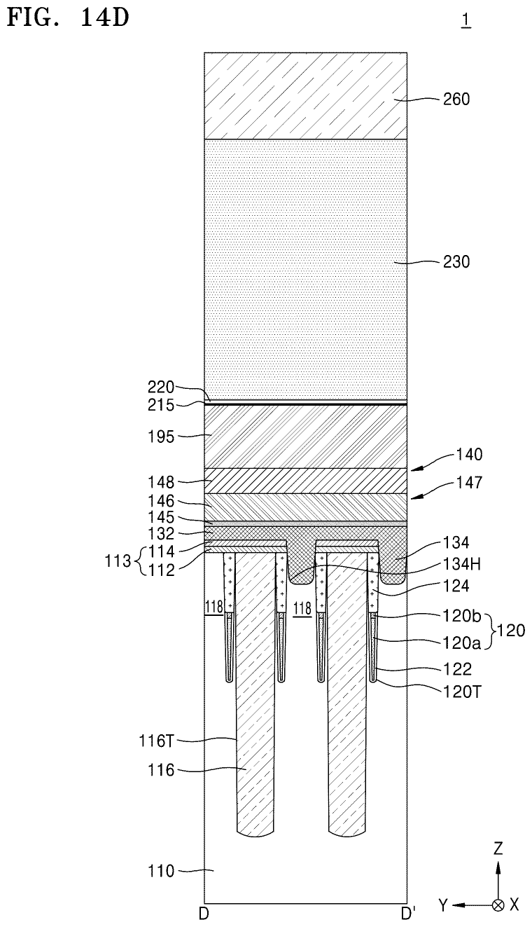

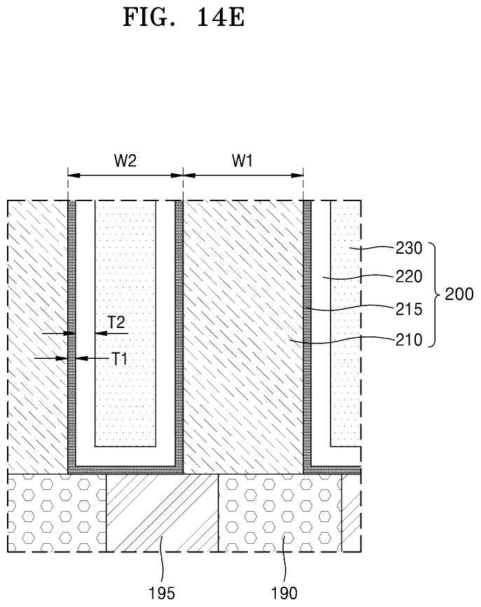

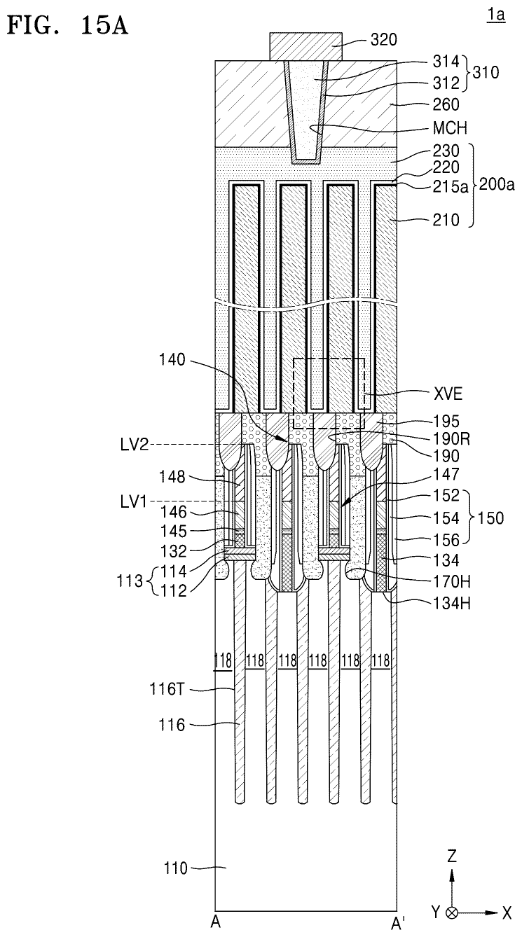

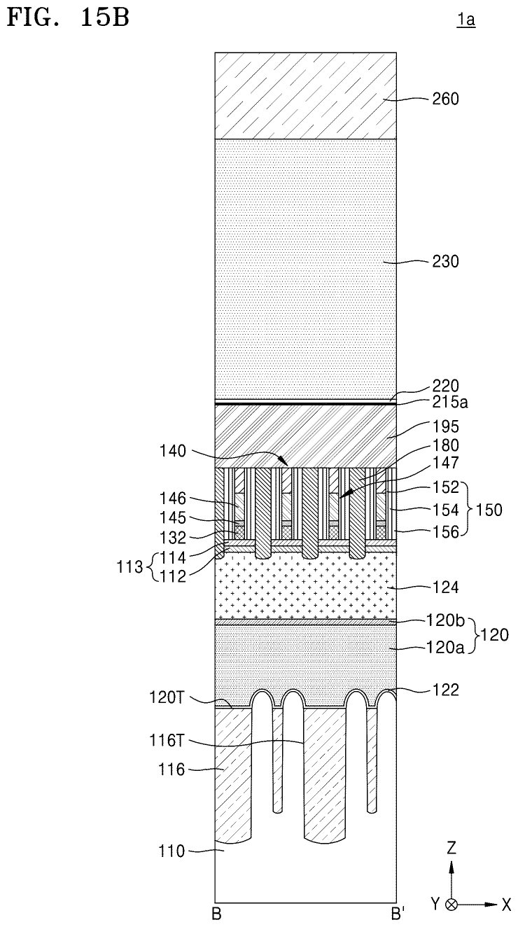

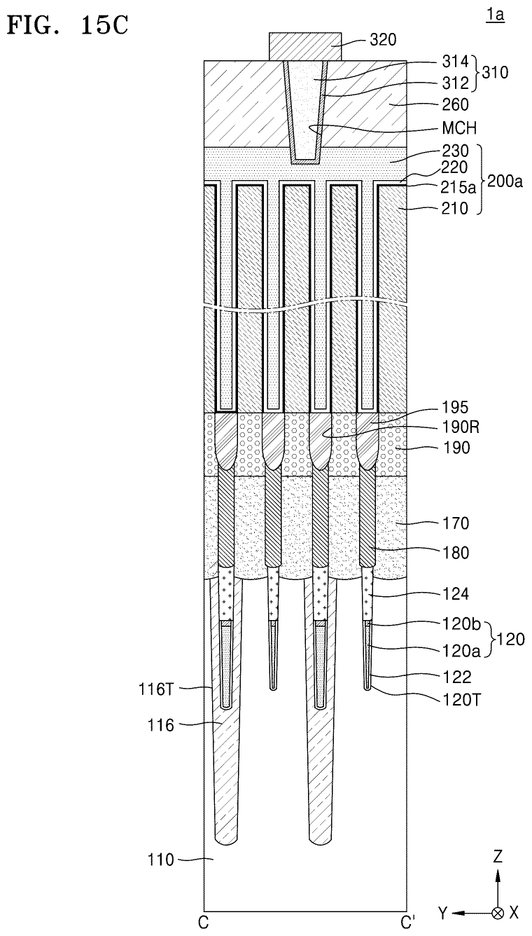

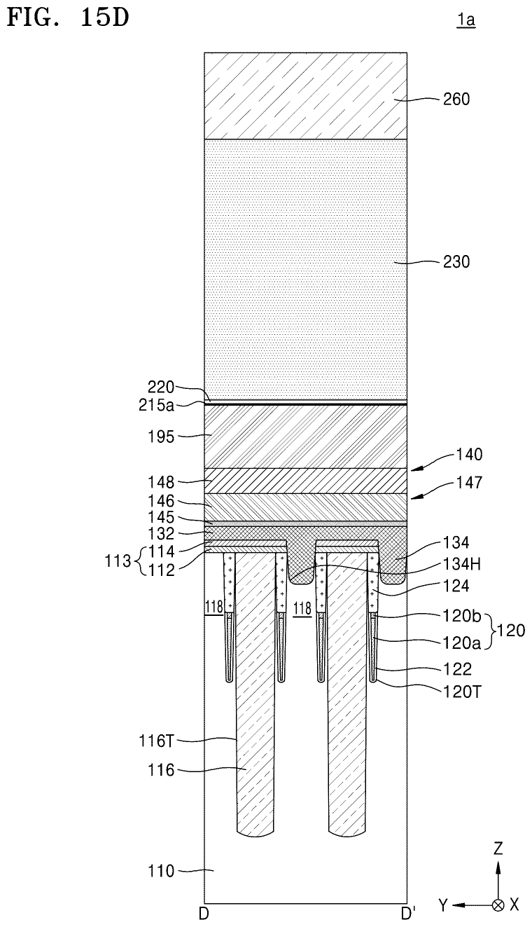

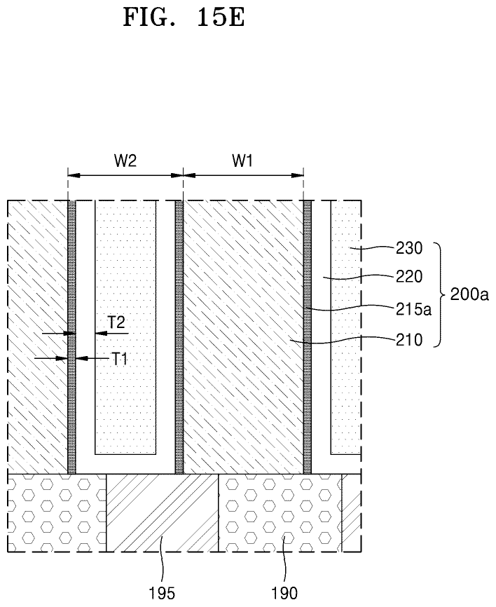

FIGS. 15A to 15E are cross-sectional views of a semiconductor memory device, according to some example embodiments. Specifically, FIG. 15A is a cross-sectional view taken along line A-A′ in FIG. 2, FIG. 15B is a cross-sectional view taken along line B-B′ in FIG. 2, FIG. 15C is a cross-sectional view taken along line C-C′ in FIG. 2, FIG. 15D is a cross-sectional view taken along line D-D′ in FIG. 2, and FIG. 15E is an enlarged cross-sectional view of portion XVE in FIG. 15A.

Referring to FIGS. 15A to 15E together, the semiconductor memory device 1a includes: a substrate 110 with a plurality of active regions 118; a plurality of gate dielectric films 122, a plurality of word lines 120, and a plurality of buried insulating films 124, which are sequentially formed inside a plurality of word line trenches 120T across the plurality of active regions 118 within the substrate 110; an insulating structure 113 covering the device isolation film 116, the plurality of active regions 118, and the plurality of buried insulating films 124; a plurality of bit line structures 140 on the insulating structure 113; a plurality of insulating spacer structures 150 covering both sidewalls of the bit line structure 140; a plurality of buried contacts 170 connected to the plurality of active regions 118 and filling a lower portion of the space defined by the plurality of insulating fences 180 and the plurality of insulating spacer structures 150 and a plurality of landing pads 190 filling an upper portion thereof and extending to an upper portion of the bit line structure 140; a plurality of capacitor structures 200a including a plurality of lower electrodes 210 connected to the plurality of landing pads 190, an electrode work function control layer 215a, a capacitor dielectric layer 220, and an upper electrode 230; and a wiring contact plug 310 connected to the upper electrode 230.

The plurality of lower electrodes 210 may each have a first horizontal width W1. The plurality of lower electrodes 210 may be spaced apart from each other by a second horizontal width W2. The second horizontal width W2 may be the minimum separation width in the horizontal direction between adjacent lower electrodes 210 among the plurality of lower electrodes 210. In some example embodiments, the second horizontal width W2 may have a value greater than the first horizontal width W1.

In some example embodiments, the electrode work function control layer 215a may cover the exposed surfaces of each of the plurality of lower electrodes 210 and may not cover the exposed surfaces of each of the plurality of landing pads 190 and the filling insulating layer 195. The electrode work function control layer 215a may be selectively formed on the exposed surfaces of each of the plurality of lower electrodes 210. For example, the electrode work function control layer 215a may selectively cover the top surface and sidewalls of each of the plurality of lower electrodes 210. In some example embodiments, by performing surface treatment before forming the electrode work function control layer 215a, the electrode work function control layer 215a may not be formed on the exposed surfaces of each of the plurality of landing pads 190 and the filling insulating layer 195 and the electrode work function control layer 215a may be selectively formed only on the exposed surfaces of each of the plurality of lower electrodes 210.

The electrode work function control layer 215a may have a first thickness T1 that is uniform or substantially uniform and may cover the exposed surfaces of each of the plurality of lower electrodes 210. For example, the electrode work function control layer 215a may cover the top surface and sidewalls of each of the plurality of lower electrodes 210 and may not cover the portion of the top surface of each of the plurality of landing pads 190 and the portion of the top surface of the filling insulating layer 195, which are not covered by the plurality of lower electrodes 210. The electrode work function control layer 215a may include a monomolecular film including an organic material. The capacitor dielectric layer 220 may cover the electrode work function control layer 215a. The capacitor dielectric layer 220 may further cover the electrode work function control layer 215a and the portion of the top surface of each of the plurality of landing pads 190 and the portion of the top surface of the filling insulating layer 195, which are not covered by the plurality of lower electrodes 210. For example, the capacitor dielectric layer 220 may cover the exposed surfaces of each of the electrode work function control layer 215a, the plurality of landing pads 190, and the filling insulating layer 195.

In some example embodiments, the capacitor dielectric layer 220 may have a second thickness T2 that is uniform or substantially uniform and may cover the electrode work function control layer 215a. The second thickness T2 may have a value greater than the first thickness T1.

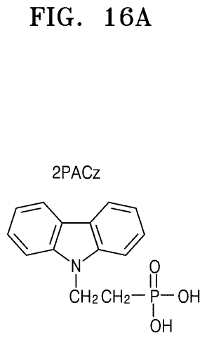

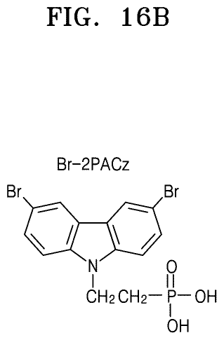

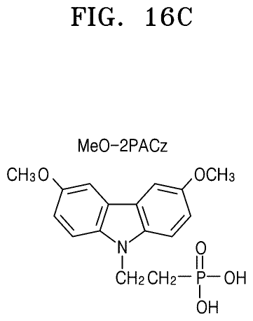

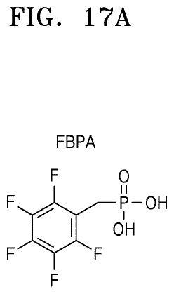

FIGS. 16A to 16C and FIGS. 17A to 17C are diagrams illustrating example materials forming an electrode work function control layer according to a method of manufacturing a semiconductor memory device, according to some example embodiments.

Referring to FIGS. 16A to 16C, the electrode work function control layer may include phosphonic acid. For example, the electrode work function control layer may include a carbazole-based material with phosphonic acid as a fixed group. In some example embodiments, the electrode work function control layer may include 2PACz ([2-(9H-carbazol-9-yl)ethyl]phosphonic acid) shown in FIG. 16A, Br-2PACz ([2-(3,6-Dibromo-9H-carbazol-9-yl)ethyl]phosphonic acid) shown in FIG. 16B, or MeO-2PACz ([2-(3,6-Dimethoxy-9H-carbazol-9-yl)ethyl]phosphonic acid) shown in FIG. 16C. However, example embodiments are not limited thereto.

Referring to FIGS. 17A to 17C, in some example embodiments, the electrode work function control layer may include FBPA (2,3,4,5,6-Pentafluorobenzylphosphonic acid) shown in FIG. 17A, TIPs (6, 13-Bis(triisopropylsilylethynyl)pentacene) shown in FIG. 17B, or 4-FTP (4-fluorothiophenol) shown in FIG. 17C. However, example embodiments are not limited thereto.

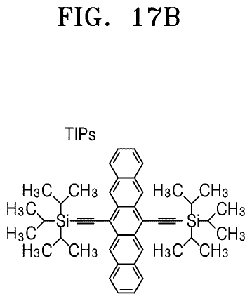

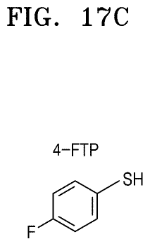

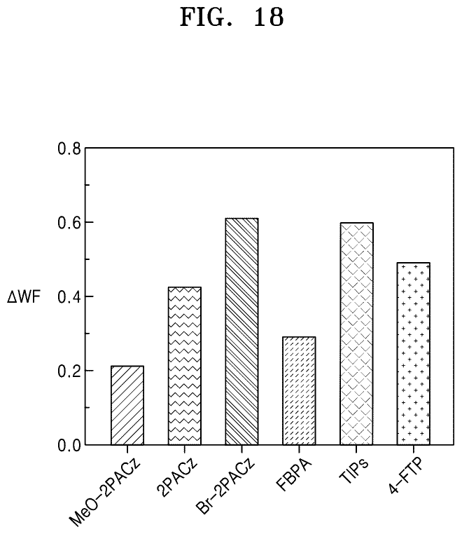

FIG. 18 is a graph showing a work function change value for each example material forming an electrode work function control layer, according to some example embodiments. FIG. 18 shows work function change values obtained by comparing a case where the electrode work function control layer 215 shown in FIGS. 14A to 14E or the electrode work function control layer 215a shown in FIGS. 15A to 15E covers the lower electrode 210 among the lower electrode 210 and the capacitor dielectric layer 220 to a case where the capacitor dielectric layer 220 directly covers the lower electrode 210.

Referring to FIG. 18, when the electrode work function control layer includes 2PACz, Br-2PACz, MeO-2PACz, FBPA, TIPs, or 4-FTP, the work function change value AWF represents a positive value. The work function change value AWF may increase or decrease depending on the material that makes up the lower electrode covered by the electrode work function control layer. For example, when the electrode work function control layer is 2PACz, the work function change value AWF may be about +0.41 eV, when the electrode work function control layer is Br-2PACz, the work function change value ΔWF may be about +0.62 eV, when the electrode work function control layer is MeO-2PACz, the work function change value ΔWF may be about +0.21 eV, when the electrode work function control layer is FBPA, the work function change value ΔWF may be about +0.3 eV, when the electrode work function control layer is TIPs, the work function change value ΔWF may be about +0.6 eV, and when the electrode work function control layer is 4-FTP, the work function change value ΔWF may be about +0.51 eV.

When the lower electrode has a relatively low work function or the capacitor dielectric layer has a relatively narrow bandgap, the energy barrier height between the lower electrode and the capacitor dielectric layer may decrease, thereby increasing leakage current. When the electrode work function control layer covering the lower electrode is positioned between the lower electrode and the capacitor dielectric layer, the work function of the lower electrode may be adjusted by the electrode work function control layer, thereby adjusting the energy barrier height between the lower electrode covered by the electrode work function control layer and the capacitor dielectric layer. For example, when the work function change value ΔWF by the electrode work function control layer has a positive value, the energy barrier height between the lower electrode covered by the electrode work function control layer and the capacitor dielectric layer may increase, thereby reducing the leakage current.

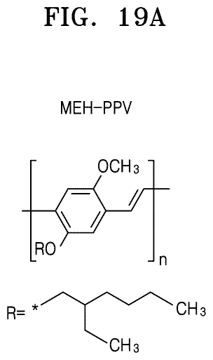

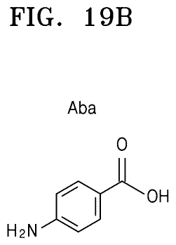

FIGS. 19A and 19B are diagrams illustrating example materials forming an electrode work function control layer according to a method of manufacturing a semiconductor memory device, according to some example embodiments.

Referring to FIGS. 19A and 19B, in some example embodiments, the electrode work function control layer may include MEH-PPV (Poly [2-methoxy-5-(2-ethylhexyloxy)-1,4-phenylenevinylene]) shown in FIG. 19A or Aba (4-Aminobenzoic acid) shown in FIG. 19B.

FIG. 20 is a graph showing a work function change value for each example material forming an electrode work function control layer, according to some example embodiments. FIG. 20 shows work function change values obtained by comparing a case where the electrode work function control layer 215 shown in FIGS. 14A to 14E or the electrode work function control layer 215a shown in FIGS. 15A to 15E covers the lower electrode 210 among the lower electrode 210 and the capacitor dielectric layer 220 to a case where the capacitor dielectric layer 220 directly covers the lower electrode 210.

Referring to FIG. 20, when the electrode work function control layer includes MEH-PPV or Aba, the work function change value ΔWF represents a negative value. The work function change value ΔWF may increase or decrease depending on the material that makes up the lower electrode covered by the electrode work function control layer. For example, when the electrode work function control layer is MEH-PPV, the work function change value ΔWF may be about-0.8 eV to about-1.0 eV, and when the electrode work function control layer is Aba, the work function change value ΔWF may be about +0.49 eV.

Referring to FIGS. 18 and 20, depending on the material that makes up the electrode work function control layer, the work function change value ΔWF may have a positive or negative value and the absolute value of the work function change value ΔWF may also vary. Accordingly, when the electrode work function control layer is selected in consideration of the materials that make up each of the lower electrode and the capacitor dielectric layer, and/or the desired characteristics of the semiconductor memory device including the same, the energy barrier height between the lower electrode and the capacitor dielectric layer may be adjusted, thereby potentially improving reliability of the semiconductor memory device.

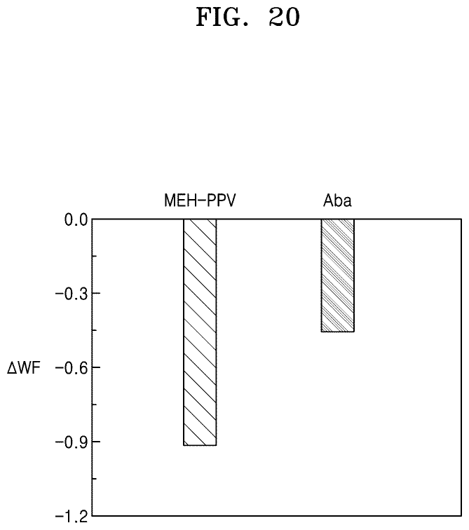

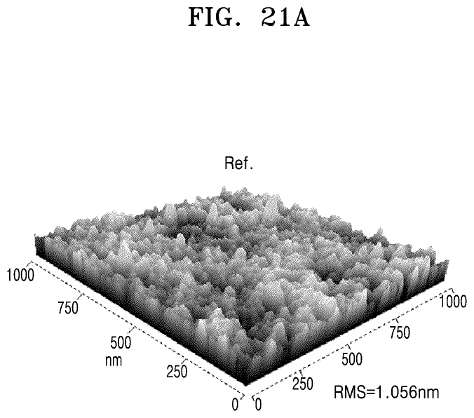

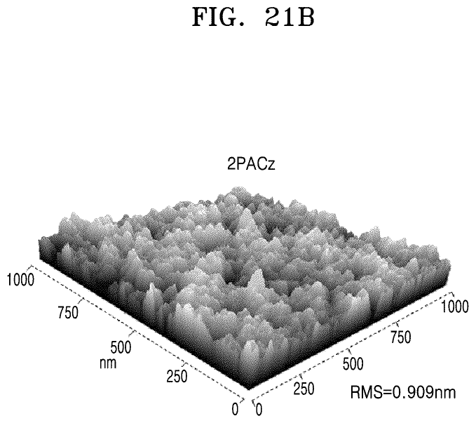

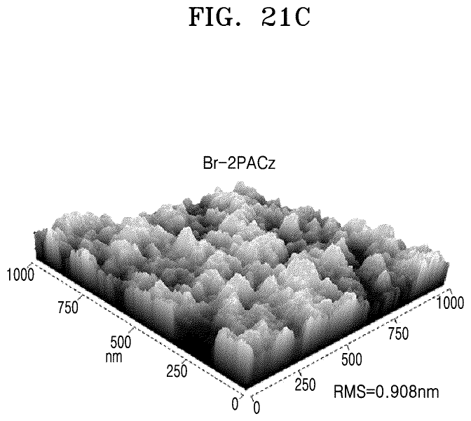

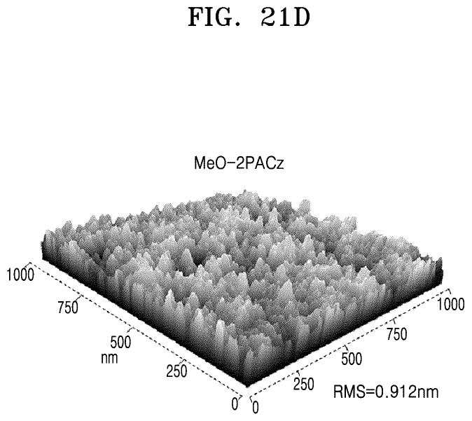

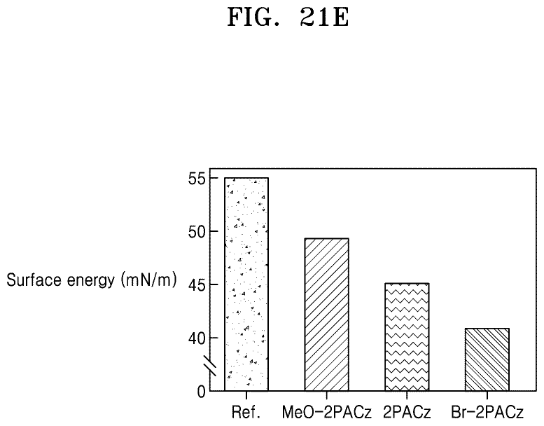

FIGS. 21A to 21E are diagrams which compare example materials forming an electrode work function control layer for surface roughness and surface energy, according to some example embodiments. FIG. 21A shows the surface roughness of the capacitor dielectric layer when the electrode work function control layer is not formed, FIGS. 21B to 21D show the surface roughness of the capacitor dielectric layer according to example materials making up the electrode work function control layer, and FIG. 21E is a graph which compares example materials forming the electrode work function control layer for surface energy.

Referring to FIGS. 21A to 21E together, when the electrode work function control layer is formed (FIGS. 21B to 21D), the surface roughness may be reduced compared to when the electrode work function control layer is not formed (FIG. 21A). For example, when the electrode work function control layer is not formed (Ref.), the root mean square (RMS) of the surface roughness measured by atomic force microscopy (AFM) is about 1.056 nm. For example, when the electrode work function control layer is 2PACz (FIG. 21B), the RMS of the surface roughness is about 0.909 nm, when the electrode work function control layer is Br-2PACz (FIG. 21C), the RMS of the surface roughness is about 0.908 nm, and when the electrode work function control layer is MeO-2PACz (FIG. 21D), the RMS of the surface roughness is about 0.912 nm, which may be reduced compared to when the electrode work function control layer is not formed (Ref.).

In addition, when the electrode work function control layer is formed, the surface energy may be reduced compared to when the electrode work function control layer is not formed (Ref.). For example, when the electrode work function control layer is not formed (Ref.), the surface energy is about 55 mN/m. For example, when the electrode work function control layer is 2PACz, the surface energy is about 45 mN/m, when the electrode work function control layer is Br-2PACz, the surface energy is about 41 mN/m, and when the electrode work function control layer is MeO-2PACz, the surface energy is about 49 mN/m, which may be reduced compared to when the electrode work function control layer is not formed (Ref.).

Therefore, when the electrode work function control layer is formed, the surface roughness and the surface energy may be reduced, thereby improving the surface characteristics of the capacitor dielectric layer and/or reducing the leakage current. Therefore, a semiconductor memory device with improved reliability may be implemented.

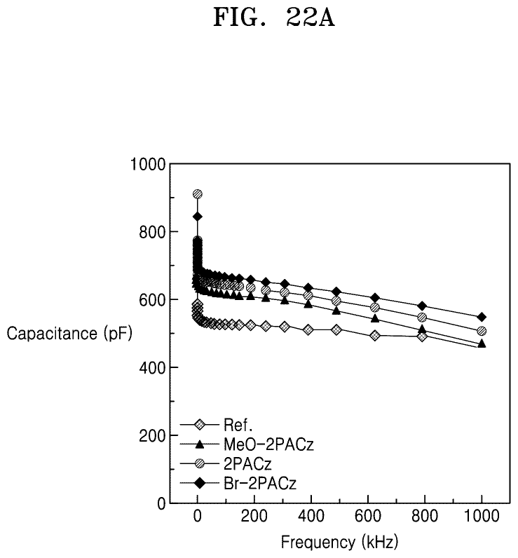

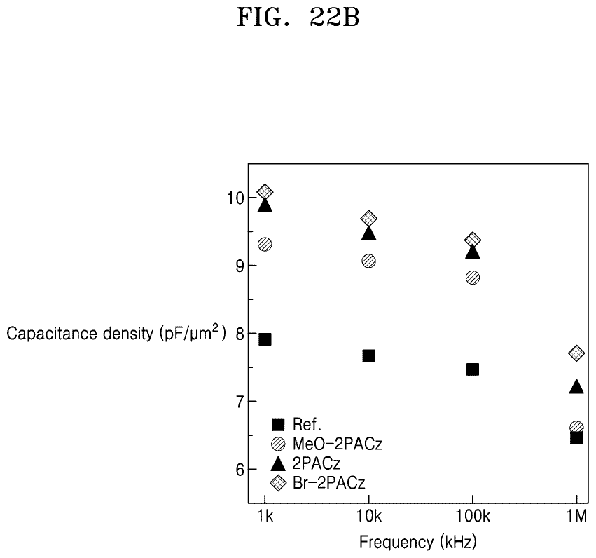

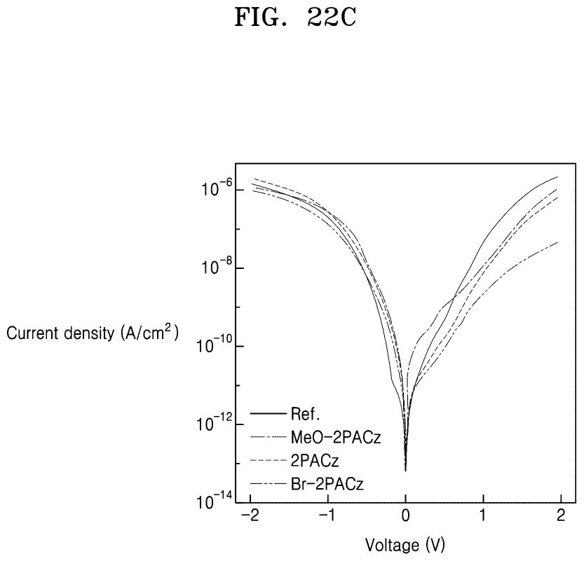

FIGS. 22A to 22C are diagrams showing electrical characteristics of a capacitor structure for each example material forming an electrode work function control layer, according to some example embodiments. FIG. 22A shows the capacitance-frequency characteristics of the capacitor structure, FIG. 22B shows the capacitance density by frequency of the capacitor structure, and FIG. 22C shows the current density-voltage characteristics of the capacitor structure.

Referring to FIG. 22A, the case where the electrode work function control layer is not formed (Ref.) and the case where the electrode work function control layer is formed (2PACz, Br-2PACz, and MeO-2PACz) each show similar values of capacitance in the low frequency region. However, as the frequency increases, the capacitance decreases relatively significantly in the case where the electrode work function control layer is not formed (Ref.) but the capacitance may be reduced relatively little and shows a relatively constant capacitance over a wide frequency band in the case where the electrode work function control layer is formed (2PACz, Br-2PACz, and MeO-2PACz).

Referring to FIG. 22B, each case where the electrode work function control layer is formed (2PACz, Br-2PACz, and MeO-2PACz) shows a relatively greater capacitance density than the case where the electrode work function control layer is not formed (Ref.).

Referring to FIG. 22C, each case where the electrode work function control layer is formed (2PACz, Br-2PACz, and MeO-2PACz) has a relatively lower current density than the case where the electrode work function control layer is not formed (Ref.), thereby showing that the leakage current may be reduced.

Accordingly, by forming the electrode work function control layer, the semiconductor memory device may be implemented with relatively constant capacitance over a wide frequency band, increased capacitance density, and/or attenuated leakage current, thereby potentially improving reliability of the semiconductor memory device.

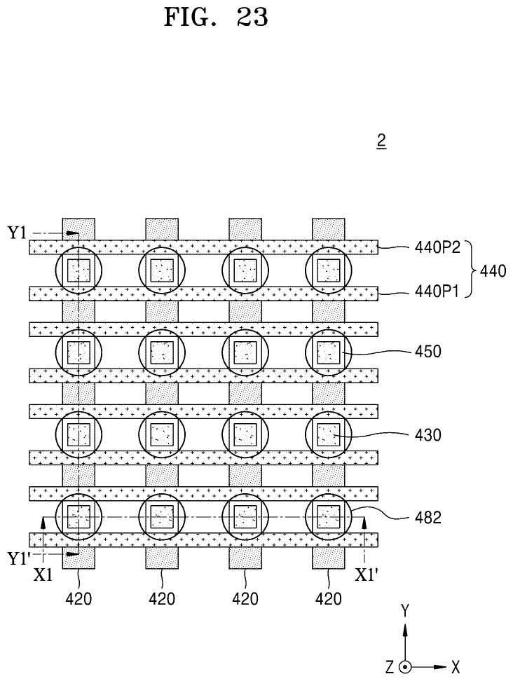

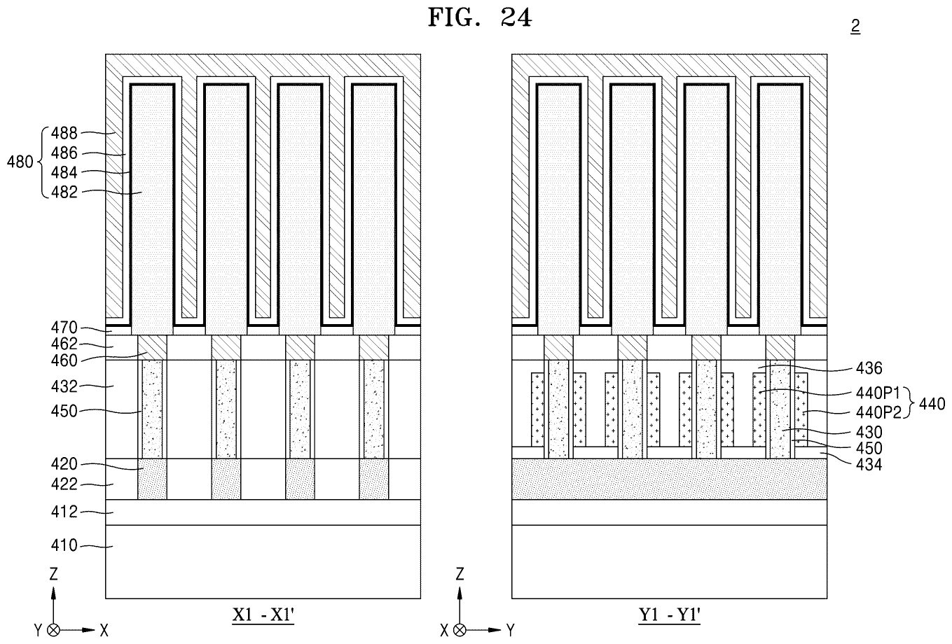

FIG. 23 is a layout diagram of a semiconductor memory device according to some example embodiments and FIG. 24 is a cross-sectional view taken along line X1-X1′ and line Y1-Y1′ in FIG. 23.

Referring to FIGS. 23 and 24, a semiconductor memory device 2 may include a substrate 410, a plurality of first conductive lines 420, a channel layer 430, a gate electrode 440, a gate insulating layer 450, and a capacitor structure 480. The semiconductor memory device 2 may include a memory device including a vertical channel transistor (VCT). The VCT may refer to a structure in which the channel length of the channel layer 430 extends from the substrate 410 in the vertical direction.

A lower insulating layer 412 may be positioned on the substrate 410 and the plurality of first conductive lines 420 may be spaced apart from each other in the first horizontal direction (X direction) and extend in the second horizontal direction (Y direction) on the lower insulating layer 412. On the lower insulating layer 412, a plurality of first insulating patterns 422 may be arranged to fill the space between the plurality of first conductive lines 420. The plurality of first insulating patterns 422 may be extended in the second horizontal direction (Y direction) and the top surfaces of the plurality of first insulating patterns 422 may be positioned at the same level as the top surfaces of the plurality of first conductive lines 420. The plurality of first conductive lines 420 may function as bit lines of the semiconductor memory device 2.

In some example embodiments, the plurality of first conductive lines 420 may include doped polysilicon, a metal, a conductive metal nitride, a conductive metal silicide, a conductive metal oxide, or a combination thereof. For example, the plurality of first conductive lines 420 include doped polysilicon, Al, Cu, Ti, Ta, Ru, W, molybdenum (Mo), platinum (Pt), Ni, Co, TiN, TaN, WN, niobium nitride (NbN), TiAl, TiAlN, TiSi, TiSiN, TaSi, TaSiN, RuTiN, NiSi, CoSi, iridium oxide (IrOₓ), RuOₓ, or a combination thereof but example embodiments are not limited thereto. The plurality of first conductive lines 420 may include a single layer or multiple layers of the aforementioned materials. In some example embodiments, the plurality of first conductive lines 420 may include a two-dimensional semiconductor material. For example, the two-dimensional semiconductor material may include graphene, carbon nanotubes, or a combination thereof. However, example embodiments are not limited thereto.

The channel layers 430 may be arranged in a matrix form where the channel layers 430 are spaced apart from each other in the first horizontal direction (X direction) and the second horizontal direction (Y direction) on the plurality of first conductive lines 420. The channel layer 430 may have a first width in the first horizontal direction (X direction) and a first height in the third direction (Z direction), wherein the first height may be greater than the first width. For example, the first height may be about 2 to 10 times the first width but is not limited thereto. A bottom portion of the channel layer 430 may function as a first source/drain region (not shown), an upper portion of the channel layer 430 may function as a second source/drain region (not shown), and a portion of the channel layer 430 between the first and second source/drain regions may function as a channel region (not shown).

In some example embodiments, channel layer 430 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. However, example embodiments are not limited thereto. The channel layer 430 may include a single layer or multiple layers of the oxide semiconductor. In some example embodiments, the channel layer 430 may have a bandgap energy greater than that of Si. For example, the channel layer 430 may have a bandgap energy of about 1.5 eV to about 5.6 eV. For example, the channel layer 430 may have optimal channel performance when the channel layer 430 has a band gap energy of about 2.0 eV to about 4.0 eV. For example, the channel layer 430 may include polycrystalline or amorphous but is not limited thereto. In some example embodiments, the channel layer 430 may include a two-dimensional semiconductor material. For example, the two-dimensional semiconductor material may include graphene, carbon nanotubes, or a combination thereof. However, example embodiments are not limited thereto.

The gate electrodes 440 may extend in the first horizontal direction (X direction) on both sidewalls of the channel layer 430. The gate electrodes 440 may include a first sub-gate electrode 440P1 facing a first sidewall of the channel layer 430 and a second sub-gate electrode 440P2 facing a second sidewall opposite the first sidewall of the channel layer 430. As one channel layer 430 is positioned between the first sub-gate electrode 440P1 and the second sub-gate electrode 440P2, the semiconductor memory device 2 may have a dual gate transistor structure. However, the inventive concepts are not limited thereto. The second sub-gate electrode 440P2 may be omitted and only the first sub-gate electrode 440P1 facing the first sidewall of the channel layer 430 may be formed, thereby implementing a single gate transistor structure.

The gate electrode 440 may include doped polysilicon, a metal, a conductive metal nitride, a conductive metal silicide, a conductive metal oxide, or a combination thereof. For example, the gate electrode 440 includes a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof but example embodiments are not limited thereto.

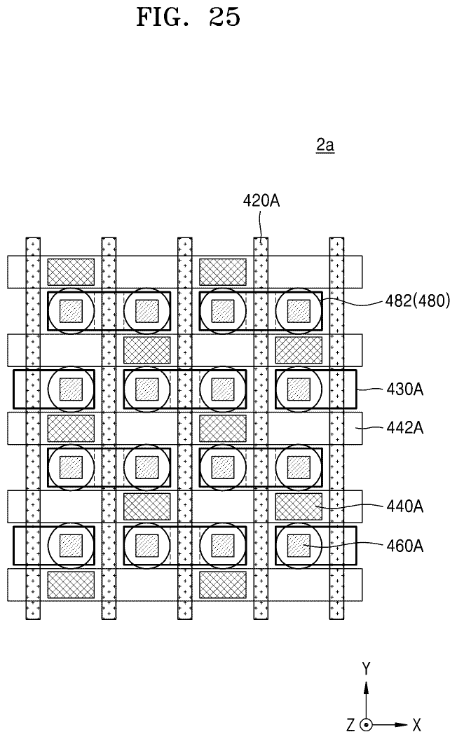

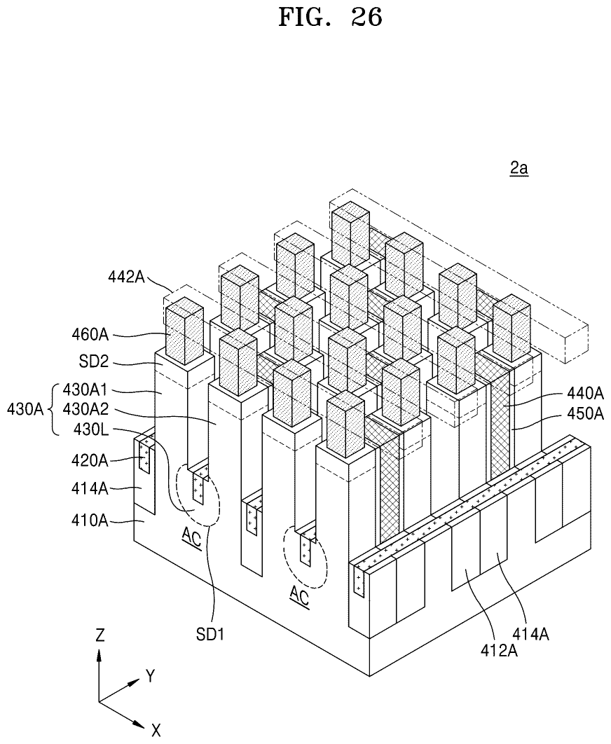

The gate insulating layer 450 may surround the sidewalls of the channel layer 430 and may be positioned between the channel layer 430 and the gate electrode 440. For example, as shown in FIG. 25, all sidewalls of the channel layer 430 may be surrounded by the gate insulating layer 450 and portions of the sidewalls of the gate electrode 440 may be in contact with the gate insulating layer 450. In other embodiments, the gate insulating layer 450 may extend in the direction in which the gate electrode 440 extends (i.e., in the first horizontal direction (X direction)) and only the two sidewalls, among the sidewalls of the channel layer 430, facing the gate electrode 440 may be in contact with the gate insulating layer 450.

In some example embodiments, the gate insulating layer 450 may include a SiO film, a SiON film, a high-k dielectric film with a higher dielectric constant than the SiO film, or a combination thereof. The high-k dielectric film may include metal oxide or metal oxynitride. For example, the high-k dielectric film that can be used as the gate insulating layer 450 may include HfO₂, HfSiO, HfSiON, HfTaO, HfTiO, HfZrO, ZrO₂, Al₂O₃, or a combination thereof but example embodiments are not limited thereto.

On the plurality of first insulating patterns 422, the plurality of second insulating patterns 432 may extend in the second horizontal direction (Y direction) and the channel layer 430 between two adjacent second insulating patterns 432 among the plurality of second insulating patterns 432 may be positioned. In addition, between two adjacent second insulating patterns 432, a first buried layer 434 and a second buried layer 436 may be positioned in the space between two adjacent channel layers 430. The first buried layer 434 may be positioned at the bottom of the space between two adjacent channel layers 430 and the second buried layer 436 may fill the remainder of the space between the two adjacent channel layers 430 on the first buried layer 434. The top surface of the second buried layer 436 is positioned at the same level as the top surface of the channel layer 430 and the second buried layer 436 may cover the top surface of the gate electrode 440. Alternatively, the plurality of second insulating patterns 432 may be formed as a material layer that is continuous with the plurality of first insulating patterns 422 or the second buried layer 436 may be formed as a material layer that is continuous with the first buried layer 434.

A capacitor contact 460 may be positioned on the channel layer 430. The capacitor contacts 460 may vertically overlap the channel layers 30 and may be arranged in a matrix form where the capacitor contacts 460 are spaced apart in the first horizontal direction (X direction) and the second horizontal direction (Y direction). The capacitor contacts 460 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but example embodiments are not limited thereto. An upper insulating layer 462 may surround the sidewalls of the capacitor contacts 460 on the plurality of second insulating patterns 432 and the second buried layer 436.

An etch stop film 470 may be positioned on the upper insulating layer 462 and a capacitor structure 480 may be positioned on the etch stop film 470. The capacitor structure 480 may include a lower electrode 482, an electrode work function control layer 484, a capacitor dielectric layer 486, and an upper electrode 488.

The lower electrode 482 may penetrate the etch stop film 470 and may be electrically connected to the top surface of the capacitor contact 460. The lower electrode 482 may be formed as a pillar type extending in the third direction (Z direction) but is not limited thereto. In some example embodiments, the lower electrodes 482 may be arranged to vertically overlap the capacitor contacts 460 and may be arranged in a matrix form where the lower electrodes 482 are spaced apart in the first horizontal direction (X direction) and the second horizontal direction (Y direction). Alternatively, a landing pad (not shown) may be further positioned between the capacitor contact 460 and the lower electrode 482 so that the lower electrode 482 may be arranged in a hexagonal shape.

The lower electrode 482, the capacitor dielectric layer 486, and the upper electrode 488 may include the lower electrode 210, the capacitor dielectric layer 220, and the upper electrode 230 shown in FIGS. 14A to 15E and the electrode work function control layer 484 may include any one of the electrode work function control layers 215 and 215a shown in FIGS. 14A to 15E.

FIG. 25 is a layout diagram of a semiconductor memory device according to some example embodiments and FIG. 26 is a perspective view of a semiconductor memory device.

Referring to FIGS. 25 and 26 together, a semiconductor memory device 2a may include a substrate 410A, a plurality of first conductive lines 420A, a channel structure 430A, a contact gate electrode 440A, a plurality of second conductive lines 442A, and a capacitor structure 480. The semiconductor memory device 2a may include a memory device including a VCT.

In the substrate 410A, a plurality of active regions AC may be defined by the first device isolation film 412A and the second device isolation film 414A. The channel structure 430A may be positioned within each active region AC and may include a first active pillar 430A1 and a second active pillar 430A2, each extending in the vertical direction, and a connecting portion 430L connected to the bottom of the first active pillar 430A1 and the bottom of the second active pillar 430A2. A first source/drain region SD1 may be positioned within the connecting portion 430L and a second source/drain region SD2 may be positioned above the first and second active pillars 430A1 and 230A2. The first active pillar 430A1 and the second active pillar 430A2 may each constitute independent unit memory cells.

The plurality of first conductive lines 420A may extend in a direction intersecting each of the plurality of active regions AC, for example, in the second horizontal direction (Y direction). A first conductive line 420A which is one of the plurality of first conductive lines 420A may be positioned on the connecting portion 430L between the first active pillar 430A1 and the second active pillar 430A2 and may be positioned in the first source/drain region SD1. Another first conductive line 420A adjacent to the first conductive line 420A may be positioned between two channel structures 430A. One of the plurality of first conductive lines 420A may function as a common bit line included in two unit memory cells composed of the first active pillar 430A1 and the second active pillar 430A2 positioned on both sides of the one first conductive line 420A.

One contact gate electrode 440A may be positioned between two adjacent channel structures 430A in the second horizontal direction (Y direction). For example, the contact gate electrode 440A may be positioned between the first active pillar 430A1 included in one channel structure 430A and the second active pillar 430A2 included in another channel structure 430A adjacent to the channel structure 430A, wherein one contact gate electrode 440A may be shared by the first active pillar 430A1 and the second active pillar 430A2 positioned on both sidewalls of the contact gate electrode 440A. A gate electrode layer 450A may be positioned between the contact gate electrode 440A and the first active pillar 430A1 and between the contact gate electrode 440A and the second active pillar 430A2. A plurality of second conductive lines 442A may extend in the first horizontal direction (X direction) on the top surface of the contact gate electrode 440A. The plurality of second conductive lines 442A may function as word lines of the semiconductor memory device 2a.

A capacitor contact 460A may be positioned on the channel structure 430A. The capacitor contact 460A may be positioned on the second source/drain region SD2 and the capacitor structure 480 may be positioned on the capacitor contact 460A. The capacitor structure 480 may include any one of the capacitor structures 200 and 200a shown in FIGS. 14A to 15E and may include any one of the electrode work function control layers 215 and 215a shown in FIGS. 14A to 15E.

The semiconductor memory device 2a may further include a wiring contact plug 310 and a wiring line 320 shown in FIGS. 14A to 15E.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the inventive concepts has been particularly shown and described with reference to example embodiments thereof, it will be understood that various changes in form and details may be made therein without departing from the spirit and scope of the following claims.

What is claimed is:

1. A method of manufacturing a semiconductor memory device, the method comprising:
preparing a substrate with a plurality of active regions defined by a device isolation film;
forming, on the substrate, a plurality of lower electrodes electrically connected to the plurality of active regions;
forming an electrode work function control layer, the electrode work function control layer including an organic material and conformally covering the plurality of lower electrodes;
forming a capacitor dielectric layer on the plurality of lower electrodes covered by the electrode work function control layer; and
forming an upper electrode on the capacitor dielectric layer, wherein the plurality of lower electrodes, the electrode work function control layer, the capacitor dielectric layer, and the upper electrode form a plurality of capacitor structures.

2. The method of claim 1, wherein the electrode work function control layer comprises a self-assembled monolayer arranged by chemical adsorption on surfaces of the plurality of lower electrodes.

3. The method of claim 1, wherein the electrode work function control layer comprises a carbazole-based material with phosphonic acid as a fixed group.

4. The method of claim 3, wherein the electrode work function control layer comprises 2PACz ([2-(9H-carbazol-9-yl)ethyl]phosphonic acid), Br-2PACz ([2-(3,6-Dibromo-9H-carbazol-9-yl)ethyl]phosphonic acid), or MeO-2PACz ([2-(3,6-Dimethoxy-9H-carbazol-9-yl)ethyl]phosphonic acid).

5. The method of claim 1, wherein a thickness of the electrode work function control layer is less than a thickness of the capacitor dielectric layer.

6. The method of claim 1, wherein the electrode work function control layer covers a top surface and sidewalls of each of the plurality of lower electrodes.

7. The method of claim 1, wherein the electrode work function control layer covers the plurality of lower electrodes to adjust an energy barrier height between the plurality of lower electrodes and the capacitor dielectric layer.

8. The method of claim 1, wherein the electrode work function control layer covers the plurality of lower electrodes to increase an energy barrier height between the plurality of lower electrodes and the capacitor dielectric layer.

9. A method of manufacturing a semiconductor memory device, the method comprising:
preparing a substrate with a plurality of active regions defined by a device isolation film;
forming a plurality of word lines extending across the plurality of active regions in a first horizontal direction;
forming a plurality of bit lines positioned in the plurality of active regions and extending in a second horizontal direction, the second horizontal direction being perpendicular to the first horizontal direction;
forming a plurality of buried contacts filling a lower portion of a space between the plurality of bit lines and are connected to the plurality of active regions;
forming a plurality of landing pads filling an upper portion of the space between the plurality of bit lines and extend to the plurality of bit lines;
forming a plurality of lower electrodes connected to the plurality of landing pads;
forming an electrode work function control layer covering the plurality of lower electrodes as a monomolecular film;
forming a capacitor dielectric layer on the plurality of lower electrodes covered by the electrode work function control layer; and
forming an upper electrode on the capacitor dielectric layer,
wherein the plurality of lower electrodes, the electrode work function control layer, the capacitor dielectric layer, and the upper electrode form a plurality of capacitor structures.

10. The method of claim 9, wherein
the electrode work function control layer comprises a self-assembled monolayer of an organic material, and
the self-assembled monolayer is formed by chemical adsorption on surfaces of the plurality of lower electrodes.

11. The method of claim 9, wherein
the plurality of lower electrodes comprises a titanium nitride, and
the electrode work function control layer comprises a carbazole-based material with phosphonic acid as a fixed group.

12. The method of claim 9, wherein
a thickness of the electrode work function control layer is 10 Å to 20 Å, and
a thickness of the capacitor dielectric layer is at least 4 times greater than the thickness of the electrode work function control layer.

13. The method of claim 9, wherein the forming of the plurality of landing pads comprises:
forming a landing pad material layer covering the plurality of bit lines;
removing a portion of the landing pad material layer to form a recess portion, and the plurality of landing pads being spaced apart from each other with the recess portion positioned therebetween; and
before the forming the plurality of lower electrodes, forming a filling insulating layer filling the recess portion,
wherein the electrode work function control layer covers a top surface and sidewalls of each of the plurality of lower electrodes.

14. The method of claim 13, wherein the electrode work function control layer further covers at least a portion of a top surface of each of the plurality of landing pads and at least a portion of a top surface of the filling insulating layer.

15. The method of claim 13, wherein
the electrode work function control layer covers the top surface and sidewalls of each of the plurality of lower electrodes, and
the electrode work function control layer not extending in a first or second horizontal direction to cover a top surface of each of the plurality of landing pads and a top surface of the filling insulating layer.

16. The method of claim 13, wherein the electrode work function control layer covers the plurality of lower electrodes to increase an energy barrier height between the plurality of lower electrodes and the capacitor dielectric layer.

17. The method of claim 16, wherein the electrode work function control layer comprises 2PACz ([2-(9H-carbazol-9-yl)ethyl]phosphonic acid), Br-2PACz ([2-(3,6-Dibromo-9H-carbazol-9-yl)ethyl]phosphonic acid), or MeO-2PACz ([2-(3,6-Dimethoxy-9H-carbazol-9-yl)ethyl]phosphonic acid).

18. A method of manufacturing a semiconductor memory device, the method comprising:
preparing a substrate with a plurality of active regions defined by a device isolation film;
forming a plurality of word lines extending across the plurality of active regions in a first horizontal direction;
forming, on the plurality of word lines, a plurality of bit lines extending in a second horizontal direction perpendicular to the first horizontal direction;
forming a plurality of direct contact conductive patterns connecting the plurality of bit lines to the plurality of active regions;
forming a plurality of buried contacts filling a lower portion of a space between the plurality of bit lines, and the plurality of buried contacts being connected to the plurality of active regions;
forming a landing pad material layer covering the plurality of bit lines;
removing a portion of the landing pad material layer to form a recess portion, thereby forming the plurality of landing pads to be spaced apart from each other with the recess portion positioned therebetween, and the plurality of landing pads connecting to the plurality of buried contacts;
forming a filling insulating layer filling the recess portion; and
forming a plurality of capacitor structures connected to the plurality of landing pads,
wherein the forming of the plurality of capacitor structures comprises
forming a plurality of lower electrodes connected to the plurality of landing pads on the filling insulating layer and on the plurality of landing pads,
forming an electrode work function control layer comprising a self-assembled monolayer of an organic material,
the self-assembled monolayer being formed by chemical adsorption on surfaces of the plurality of lower electrodes,
forming a capacitor dielectric layer on the plurality of lower electrodes covered by the electrode work function control layer, and
forming an upper electrode on the capacitor dielectric layer.

19. The method of claim 18, wherein
a thickness of the electrode work function control layer is less than a thickness of the capacitor dielectric layer, and
the thickness of the electrode work function control layer is 10 Å to 20 Å,
wherein the electrode work function control layer covers the surfaces of the plurality of lower electrodes to increase an energy barrier height between the plurality of lower electrodes and the capacitor dielectric layer.

20. The method of claim 18, wherein the plurality of lower electrodes comprises a titanium nitride, and wherein the electrode work function control layer comprises 2PACz ([2-(9H-carbazol-9-yl)ethyl]phosphonic acid), Br-2PACz ([2-(3,6-Dibromo-9H-carbazol-9-yl)ethyl]phosphonic acid), or MeO-2PACz ([2-(3,6-Dimethoxy-9H-carbazol-9-yl)ethyl]phosphonic acid).
